(19) United States
(12) Patent Application Publication
(10) Pub. No.: US 2026/0020271 A1
(43) Pub. Date: Jan. 15, 2026

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 19/334,947

(22) Filed: Sep. 21, 2025

Related U.S. Application Data
(63) Continuation of application No. PCT/JP2024/035494, filed on Oct. 3, 2024.

(30) Foreign Application Priority Data
Oct. 24, 2023 (JP) 2023-182416

(51) Int. Cl. H10D 12/01; H10D 12/00; H10D 62/10; H10D 64/00

(52) U.S. Cl. CPC H10D 12/038; H10D 12/415; H10D 12/481; H10D 62/109; H10D 64/117

(57) ABSTRACT

Provided is a method for manufacturing a semiconductor device, including forming a plurality of trenches at a front surface of a semiconductor substrate, forming an implantation mask in a first trench of the plurality of trenches, and implanting a dopant of a second conductivity type in a second trench, among the plurality of trenches, in which the implantation mask is not formed, to form a trench bottom portion in a bottom portion of the second trench, wherein in the implanting the dopant, the dopant of the second conductivity type is also implanted in a first mesa portion adjacent to the first trench and a second mesa portion adjacent to the second trench.

The contents of the following patent application(s) are incorporated herein by reference:
NO. 2023-182416 filed in JP on Oct. 24, 2023
NO. PCT/JP2024/035494 filed in WO on Oct. 3, 2024.

### BACKGROUND

### 1. Technical Field

The present invention relates to a semiconductor device and a method for manufacturing the semiconductor device.

### 2. Related Art

Patent document 1 describes a semiconductor device provided with a barrier region of a second conductivity type in a bottom portion of a trench.

### PRIOR ART DOCUMENTS

### Patent Documents

Patent Document 1: Japanese Patent Application Publication No. 2019-110288

### BRIEF DESCRIPTION OF THE DRAWINGS

FIG. 1 illustrates an example of an upper surface of a semiconductor device 100 according to an embodiment 1.

FIG. 2A is illustrates an example of a cross section a-a′ in FIG. 1.

FIG. 2B is an enlarged drawing of a region A in FIG. 2A.

FIG. 3A illustrates an example of a manufacturing method of the semiconductor device 100 according to the embodiment 1.

FIG. 3B illustrates the example of the manufacturing method of the semiconductor device 100 according to the embodiment 1.

FIG. 4A illustrates another example of the manufacturing method of the semiconductor device 100 according to the embodiment 1.

FIG. 4B illustrates another example of the manufacturing method of the semiconductor device 100 according to the embodiment 1.

FIG. 5A illustrates another example of the manufacturing method of the semiconductor device 100 according to the embodiment 1.

FIG. 5B illustrates another example of the manufacturing method of the semiconductor device 100 according to the embodiment 1.

FIG. 6A illustrates another example of the manufacturing method of the semiconductor device 100 according to the embodiment 1.

FIG. 6B illustrates another example of the manufacturing method of the semiconductor device 100 according to the embodiment 1.

FIG. 6C illustrates another example of the manufacturing method of the semiconductor device 100 according to the embodiment 1.

FIG. 7A illustrates an example of a cross section of a semiconductor device 200 according to an embodiment 2.

FIG. 7B illustrates an example of a cross section of a semiconductor device 300 according to an embodiment 3.

FIG. 7C illustrates an example of a cross section of a semiconductor device 400 according to an embodiment 4.

FIG. 8A illustrates another example of the manufacturing method of the semiconductor device 100 according to the embodiment 1.

FIG. 8B illustrates another example of the manufacturing method of the semiconductor device 100 according to the embodiment 1.

FIG. 8C illustrates another example of the manufacturing method of the semiconductor device 100 according to the embodiment 1.

FIG. 8D illustrates another example of the manufacturing method of the semiconductor device 100 according to the embodiment 1.

FIG. 9A illustrates another example of the cross section of the semiconductor device 200 according to the embodiment 2.

FIG. 9B illustrates another example of the cross section of the semiconductor device 300 according to the embodiment 3.

FIG. 9C illustrates another example of the cross section of the semiconductor device 400 according to the embodiment 4.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

In the present specification, one side in a direction parallel to a depth direction of a semiconductor substrate is referred to as ‘upper’ or ‘front’ and the other side is referred to as ‘lower’ or ‘back’. One surface of two principal surfaces of a substrate, a layer, or other member is referred to as a front surface, and the other surface is referred to as a back surface. “Upper” and “lower” directions are not limited to a direction of gravity, or a direction in which a semiconductor device is mounted.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type.

A chemical concentration in the present specification refers to the concentration of impurities, which is measured regardless of the state of electrical activation. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration.

In addition, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder of a crystal structure by a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

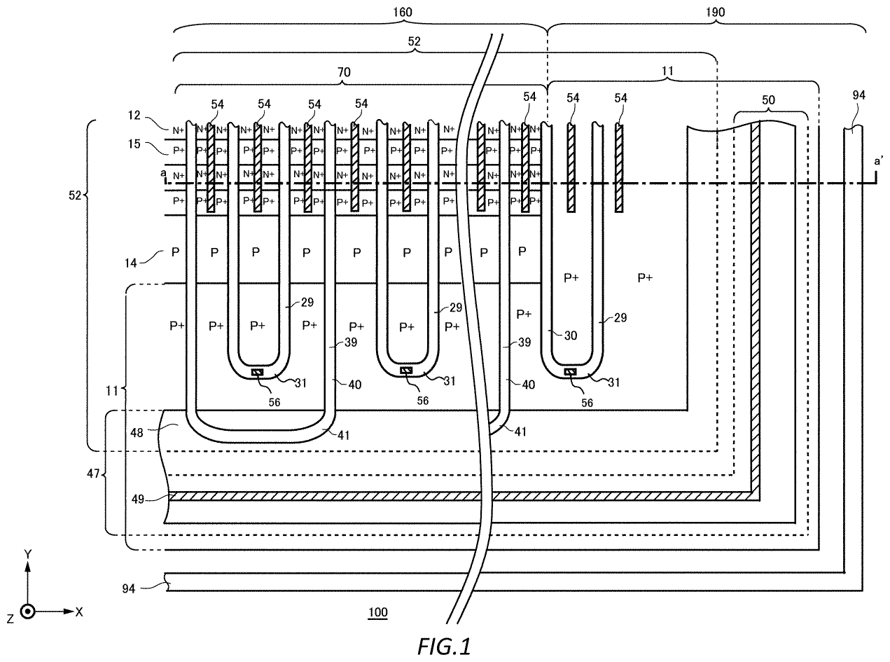

FIG. 1 illustrates an example of an upper surface of a semiconductor device 100 according to an embodiment 1. FIG. 1 illustrates a position of each member as being projected onto a front surface of a semiconductor substrate. FIG. 1 illustrates merely some members of the semiconductor device 100, and omits illustrations of some members.

The semiconductor device 100 includes the semiconductor substrate. As simply used in the present specification, a top view means a view from a side of the front surface of the semiconductor substrate. The semiconductor substrate of the present example has two sets of end sides opposite to each other in the top view. In FIG. 1, the X axis and the Y axis are parallel to any of end sides. In addition, the Z axis is perpendicular to the front surface of the semiconductor substrate.

The semiconductor substrate is provided with an active portion 160. The active portion 160 is a region where a main current flows in the depth direction between the front surface and the back surface of the semiconductor substrate when the semiconductor device 100 operates.

The active portion 160 is provided with a transistor portion 70 including a transistor element such as an IGBT. The active portion 160 may further be provided with a diode portion including a diode element such as a freewheeling diode (FWD). In the transistor portion 70, an emitter region of the N type, a base region of the P type, and a gate structure having a gate conductive portion and a gate dielectric film are periodically arranged at the front surface side of the semiconductor substrate.

The semiconductor device 100 may have one or more pads above the semiconductor substrate. The semiconductor device 100 may have a pad such as a gate pad, an anode pad, a cathode pad, and a current detection pad. Each pad is arranged in the vicinity of an end side. The vicinity of the end side refers to a region between the end side and an emitter electrode in the top view. When the semiconductor device 100 is mounted, each pad may be connected to an external circuit via a wiring line such as a wire.

A gate potential is applied to the gate pad. The gate pad is electrically connected to a conductive portion of a gate trench portion of the active portion 160. The semiconductor device 100 includes a gate runner 47 that electrically connects the gate pad and the gate trench portion.

The gate runner 47 is arranged between the active portion 160 and the end side of the semiconductor substrate in a top view. The gate runner 47 of the present example surrounds the active portion 160 in a top view. A region surrounded by the gate runner 47 in a top view may be set as the active portion 160.

The gate runner 47 is formed of either a semiconductor gate runner 48 or a gate metal layer 50, or both. The gate runner 47 of the present example includes the semiconductor gate runner 48 and the gate metal layer 50. The semiconductor gate runner 48 is arranged above the semiconductor substrate. The semiconductor gate runner 48 of the present example may be formed of a polycrystalline semiconductor such as polysilicon doped with impurities. The semiconductor gate runner 48 is electrically connected with the gate conductive portion provided inside the gate trench portion via the gate dielectric film.

The semiconductor device 100 in the present example includes an edge termination structure portion 190 provided to an outer circumference of the active portion 160. The edge termination structure portion 190 of the present example is arranged between the gate runner 47 and the end side. The edge termination structure portion 190 relaxes electric field strength at the front surface side of the semiconductor substrate.

The edge termination structure portion 190 may further include at least one of a field plate 94, and a RESURF which are annularly provided to surround the active portion 160. The field plate 94 of the present example may be a same material as the gate metal layer 50 or an emitter electrode 52 and/or a polysilicon or the like which has been doped with impurities. In the present example, descriptions of structures other than the field plate 94 in the edge termination structure portion 190 are omitted.

In addition, the semiconductor device 100 may include a temperature sensing portion (not shown) which is a PN junction diode formed of polysilicon or the like, and a current detection portion (not shown) which simulates an operation of the transistor portion provided in the active portion 160.

The semiconductor device 100 includes a gate trench portion 40, a dummy trench portion 30, a well region 11, an emitter region 12, a base region 14, and a contact region 15 which are provided at the front surface side of the semiconductor substrate. The gate trench portion 40 and the dummy trench portion 30 each are an example of the trench portion.

In addition, the semiconductor device 100 in the present example includes the gate metal layer 50 and the emitter electrode 52 which are provided above the front surface of the semiconductor substrate. The gate metal layer 50 and the emitter electrode 52 are provided separately from each other. The gate metal layer 50 and the emitter electrode 52 are electrically insulated.

Although an interlayer dielectric film is provided between the emitter electrode 52 and the gate metal layer 50, and the front surface of the semiconductor substrate, it is omitted in FIG. 1. In the interlayer dielectric film of the present example, contact holes 49, 54, and 56 are provided to pass through the interlayer dielectric film. In FIG. 1, each contact hole is obliquely hatched.

The emitter electrode 52 is provided above the gate trench portion 40, the dummy trench portion 30, the well region 11, the emitter region 12, the base region 14, and the contact region 15. The emitter electrode 52 is electrically connected to the emitter region 12, the base region 14, and the contact region 15 at the front surface of the semiconductor substrate through the contact hole 54.

In addition, the emitter electrode 52 is connected to a dummy conductive portion in the dummy trench portion 30 through the contact hole 56. A connecting portion which is formed of conductive material such as polysilicon or the like doped with impurities may be provided between the emitter electrode 52 and the dummy conductive portion. The connecting portion may be provided at the front surface of the semiconductor substrate via a dielectric film such a dummy dielectric film of the dummy trench portion 30.

The gate metal layer 50 is electrically connected to the semiconductor gate runner 48 by the contact hole 49. The semiconductor gate runner 48 may be formed of polysilicon or the like doped with impurities. The semiconductor gate runner 48 connects to the gate conductive portion in the gate trench portion 40 at the front surface of the semiconductor substrate. The semiconductor gate runner 48 is not electrically connected to the dummy conductive portion in the dummy trench portion 30 and the emitter electrode 52. When the semiconductor gate runner 48 and the gate conductive portion are not connected, or when the semiconductor gate runner 48 is not provided, the gate metal layer 50 may be connected directly with the gate conductive portion via the contact hole 49.

The semiconductor gate runner 48 and the emitter electrode 52 are electrically dissociated by an insulator such as an interlayer dielectric film or an oxide film. The semiconductor gate runner 48 of the present example is provided from below the contact hole 49 to an edge portion 41 of the gate trench portion 40. The gate conductive portion is exposed at the front surface of the semiconductor substrate at the edge portion 41 of the gate trench portion 40, and connects with the semiconductor gate runner 48.

The emitter electrode 52 and the gate metal layer 50 are formed of a conductive material including metal. For example, the emitter electrode 52 and the gate metal layer 50 are formed of an alloy containing aluminum or aluminum as a main component (for example, an aluminum-silicon alloy or the like). Each electrode may have a barrier metal formed of titanium, a titanium compound, or the like as an underlying layer of a region formed of aluminum or the like. Each electrode of the present example are the emitter electrode 52 and the gate metal layer 50, respectively.

Each electrode may have a plug formed of tungsten or the like in the contact hole. The plug may have a barrier metal on a side in contact with the semiconductor substrate and have tungsten embedded so as to be in contact with the barrier metal, and may be formed of aluminum or the like on tungsten.

The well region 11 overlaps with the gate runner 47 to extend in the outer circumference of the active portion 160, and is annularly provided in a top view. The well region 11 extends in a predetermined width even in a range without overlapping with the gate runner 47, and is annularly provided in a top view. The well region 11 of the present example is provided away from the end of the contact hole 54 in the Y axis direction toward the gate runner 47. The well region 11 is a region of a second conductivity type having a higher doping concentration than the base region 14. The gate runner 47 is electrically insulated from the well region 11.

The base region 14 of the present example is of a P type, and the well region 11 is of a P+ type. In addition, the well region 11 is formed from the front surface of the semiconductor substrate to a position deeper than a lower end of the base region 14. The base region 14 may be provided in contact with the well region 11. Therefore, the well region 11 is electrically connected to the emitter electrode 52.

The transistor portion 70 has a plurality of trench portions arrayed in an array direction. In the transistor portion 70 of the present example, one or more gate trench portions 40 are provided along the array direction.

The gate trench portion 40 in the present example may have two linear portions 39 extending along an extending direction perpendicular to the array direction (portions of a trench that are linear along the extending direction), and the edge portion 41 connecting the two linear portions 39.

At least a part of the edge portion 41 may be provided in a curved shape in a top view. The edge portion 41 connects ends of the two linear portions 39 in the Y axis direction with the semiconductor gate runner 48, and thus functions as a gate electrode to the gate trench portion 40. On the other hand, by forming the edge portion 41 into a curved shape, electric field strength at the end portions can be further relaxed as compared with a case where the gate trench portion is completed with the linear portions 39.

In another example, one or more gate trench portions 40 and one or more dummy trench portions 30 may be alternately provided along the array direction in the transistor portion 70. In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. In FIG. 1, although two dummy trench portions 30 are provided between the linear portions 39, this is merely an example and is not limiting.

The dummy trench portion 30 may not be provided between the respective linear portions 39, and the gate trench portion 40 may be provided therebetween. With such a structure, an electron current from the emitter region 12 can be increased, so that an ON voltage is reduced.

The dummy trench portion 30 may have a linear shape extending in the extending direction, and may have linear portions 29 and an edge portion 31, similar to the gate trench portion 40. In the semiconductor device 100 illustrated in FIG. 1, only the dummy trench portion 30 having the edge portion 31 is arrayed; however, in another example, the semiconductor device 100 may include the dummy trench portion 30 with a linear shape that does not have the edge portion 31.

A diffusion depth of the well region 11 may be deeper than the depth of the gate trench portion 40 and the dummy trench portion 30. End portions of the gate trench portion 40 and the dummy trench portion 30 in the Y axis direction are provided in the well region 11 in the top view. That is, the bottom portion in a depth direction of each trench portion is covered with the well region 11 at the end portion in the Y axis direction of each trench portion. In addition, the trench portion provided at the end portion in the X axis direction may be covered with the well region 11. Thereby, the electric field strength on a bottom portion of each trench portion can be relaxed.

A mesa portion is provided between the respective trench portions in the array direction. The mesa portion refers to a region sandwiched between the trench portions inside the semiconductor substrate. As an example, a depth position of the mesa portion is from the front surface of the semiconductor substrate to the bottom portion of the trench portion. The mesa portion of the present example is sandwiched between trench portions that are adjacent to each other in the X axis direction, and is provided to extend in the extending direction (the Y axis direction) along the trench at the front surface of the semiconductor substrate.

Each mesa portion is provided with the base region 14. In each mesa portion, at least one of the emitter region 12 of a first conductivity type or the contact region 15 of a second conductivity type may be provided in a region sandwiched between the base regions 14 in a top view. The emitter region 12 in the present example is the N+ type, and the contact region 15 is the P+ type. The emitter region 12 and the contact region 15 may be provided between the base region 14 and the front surface of the semiconductor substrate in the depth direction.

The mesa portion has the emitter region 12 exposed at the front surface of the semiconductor substrate. The emitter region 12 is provided in contact with the gate trench portion 40. The mesa portion in contact with the gate trench portion 40 is provided with the contact region 15 exposed at the front surface of the semiconductor substrate.

Each of the contact region 15 and the emitter region 12 in the mesa portion is provided from one trench portion to the other trench portion in the X axis direction. As an example, the contact region 15 and the emitter region 12 in the mesa portion are alternately arranged along the extending direction of the trench portion (the Y axis direction).

In another example, the contact region 15 and the emitter region 12 in the mesa portion may be provided in a stripe pattern along the extending direction of the trench portion (the Y axis direction). For example, the emitter region 12 is provided in a region in contact with the trench portion, and the contact region 15 is provided in a region sandwiched between the emitter regions 12.

The contact hole 54 is provided above each mesa portion. The contact hole 54 is arranged in a region sandwiched between the base regions 14 in its extending direction (Y axis direction). The contact hole 54 of the present example is provided above respective regions of the contact region 15, the base region 14, and the emitter region 12. The contact hole 54 may be arranged at the center of the mesa portion in the array direction (the X axis direction).

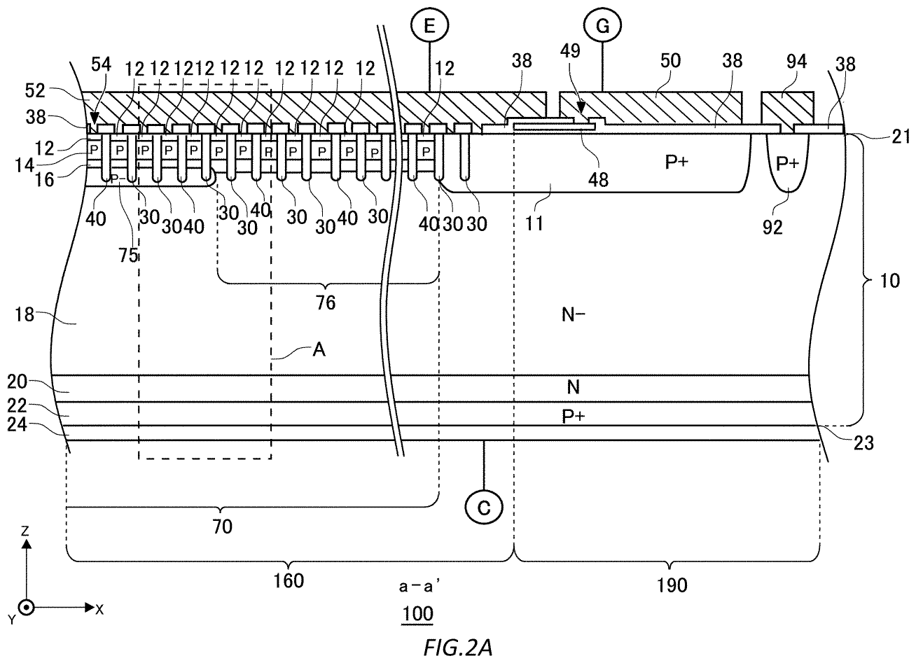

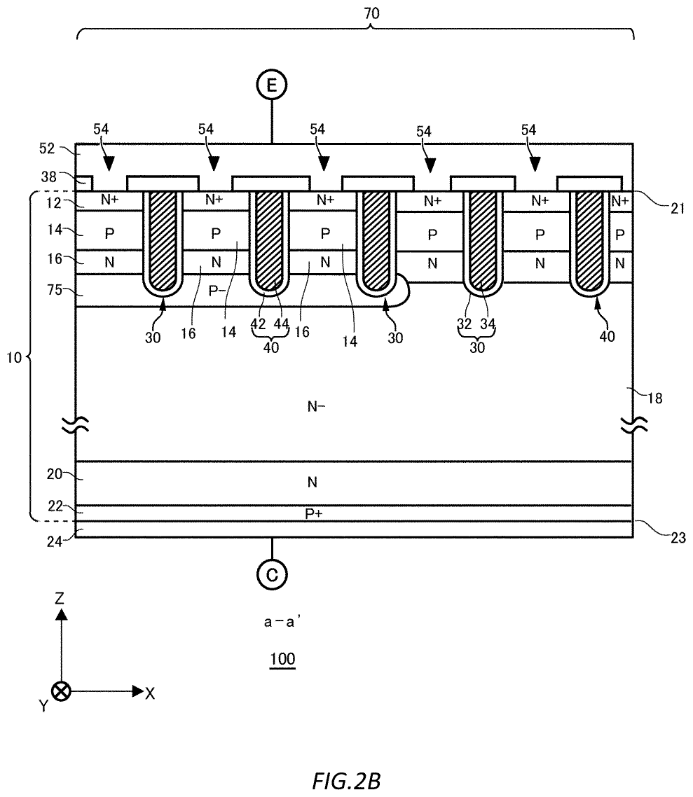

FIG. 2A is illustrates an example of a cross section a-a′ in FIG. 1. FIG. 2B is an enlarged drawing of a region A in FIG. 2A. The cross section a-a′ is an XZ plane passing through the emitter region 12, the contact region 15, the base region 14, and the gate trench portion 40 and the dummy trench portion 30. The semiconductor device 100 in the present example has a semiconductor substrate 10, an interlayer dielectric film 38, the emitter electrode 52, and a collector electrode 24 in the cross section a-a′.

The edge termination structure portion 190 may have a guard ring 92. The guard ring 92 is a region of the P type in contact with a front surface 21 of the semiconductor substrate 10. The guard ring 92 is electrically connected to the field plate 94. Note that the edge termination structure portion 190 of the present example has a plurality of guard rings, but it is omitted in FIG. 2A, and only one guard ring 92 is shown. By providing the plurality of guard rings 92, a depletion layer on the upper surface side of the active portion 160 can be extended outward, and a breakdown voltage of the semiconductor device 100 can be improved. Note that in the present example, a contact hole is illustrated in the interlayer dielectric film 38 in order to show that the guard ring 92 and the field plate 94 are electrically connected, but does not necessarily show that there is a contact hole on the a-a′ cross section.

The interlayer dielectric film 38 is provided at the front surface 21 of the semiconductor substrate 10. The interlayer dielectric film 38 is a dielectric film such as silicate glass added with impurities of, for example, boron, phosphorus, or the like. The interlayer dielectric film 38 may be in contact with the front surface 21, and another film such as an oxide film may be provided between the interlayer dielectric film 38 and the front surface 21. The interlayer dielectric film 38 is provided with the contact hole 54 described in FIG. 1.

The emitter electrode 52 is provided at the front surface 21 of the semiconductor substrate 10 and an upper surface of the interlayer dielectric film 38. The emitter electrode 52 is electrically connected to the front surface 21 through the contact hole 54 of the interlayer dielectric film 38. A plug and/or barrier metal formed of tungsten (W) or the like may be provided inside the contact hole 54. Below the contact hole provided with the plug and/or barrier metal, a plug region (not shown) of the P++ type having a doping concentration higher than that of the contact region 15 may be provided. The plug region improves contact resistance of the barrier metal and P type regions such as the well region 11, the base region 14, and the contact region 15. By improving the contact resistance between the barrier metal and the contact region 15, latch-up resistance is improved.

The collector electrode 24 is provided on a back surface 23 of the semiconductor substrate 10. The emitter electrode 52 and the collector electrode 24 are formed of a material including metal or a laminated film thereof.

The semiconductor substrate 10 may be a silicon substrate, a silicon carbide substrate, or a nitride semiconductor substrate such as gallium nitride, or the like. In the present example, the semiconductor substrate 10 is a silicon substrate.

The semiconductor substrate 10 has a drift region 18 of a first conductivity type. The drift region 18 of the present example is of the N-type. The drift region 18 may be a remaining region in the semiconductor substrate 10 in which other doping regions have not been provided.

Above the drift region 18, one or more accumulation regions 16 may be provided in the Z axis direction. The accumulation region 16 is a region where a same dopant as that of the drift region 18 is accumulated at a higher concentration than the drift region 18. The doping concentration of the accumulation region 16 is higher than the doping concentration of the drift region 18. The accumulation region 16 of the present example is the N type. The dopant of the accumulation region 16 is, as an example, arsenic (As), phosphorus (P), antimony (Sb), or the like. By providing the accumulation region 16, it is possible to increase an injection enhancement effect (IE effect) of the carrier so as to lower the ON voltage.

The accumulation region 16 of the present example may be provided between the base region 14 and a trench bottom portion 75 that is described below. In the accumulation region 16 of the present example, an upper end is in contact with the base region 14, and a lower end is in contact with the trench bottom portion 75. In another example, the drift region 18 may be interposed between the lower end of the accumulation region 16 and an upper end of the trench bottom portion 75.

Above the base region 14, the emitter region 12 is provided in contact with the front surface 21 of the semiconductor substrate 10. The emitter region 12 is provided in contact with the gate trench portion 40. The doping concentration of the emitter region 12 is higher than the doping concentration of the drift region 18. Examples of the dopant of the emitter region 12 include arsenic (As), phosphorus (P), antimony (Sb), and the like.

A buffer region 20 of a first conductivity type may be provided below the drift region 18. The buffer region 20 of the present example is the N type. A doping concentration of the buffer region 20 is higher than the doping concentration of the drift region 18. A collector region 22 is provided below the buffer region 20. The collector region 22 in the present example is of the P+ type as an example. The buffer region 20 may function as a field stop layer which prevents a depletion layer extending from a lower surface side of the base region 14, from reaching the collector region 22.

In the semiconductor substrate 10, the gate trench portion 40 and the dummy trench portion 30 are provided. The gate trench portion 40 and the dummy trench portion 30 are provided so as to pass through the base region 14 and the accumulation region 16 from the front surface 21, and reach the drift region 18. The configuration of the trench portion passing through the doping region is not limited to the one manufactured in the order of forming the doping region and then forming the trench portion. The configuration of the trench portion passing through the doping region includes a configuration of the doping region being formed between the trench portions after forming the trench portion.

The gate trench portion 40 has a gate trench, a gate dielectric film 42, and a gate conductive portion 44 that are provided at the front surface 21 of the semiconductor substrate 10. The gate dielectric film 42 is provided to cover an inner wall of the gate trench. The gate dielectric film 42 may be formed of an oxide film or a nitride film. The gate conductive portion 44 is provided so as to be embedded on an inner side further than the gate dielectric film 42 inside the gate trench. An upper surface of the gate conductive portion 44 may be in a same XY plane as the front surface 21. The gate dielectric film 42 insulates the gate conductive portion 44 from the semiconductor substrate 10. The gate conductive portion 44 is formed of polysilicon doped with impurities, or the like.

The gate conductive portion 44 may be provided to be longer than the base region 14 in the depth direction. The gate trench portion 40 is covered with the interlayer dielectric film 38 at the front surface 21. When a predetermined voltage is applied to the gate conductive portion 44, a channel is formed by an electron inversion layer in a surface layer of the base region 14 at an interface in contact with the gate trench.

The dummy trench portion 30 may have a same structure as the gate trench portion 40 in an XZ cross section. The dummy trench portion 30 has a dummy trench, a dummy dielectric film 32, and a dummy conductive portion 34 that are provided at the front surface 21 of the semiconductor substrate 10. The dummy dielectric film 32 is provided to cover an inner wall of the dummy trench. The dummy dielectric film 32 may be formed of an oxide film or a nitride film. The dummy conductive portion 34 is provided so as to be embedded on an inner side further than the dummy dielectric film 32 inside the dummy trench. An upper surface of the dummy conductive portion 34 may be in the same XY plane as the front surface 21. The dummy dielectric film 32 insulates the dummy conductive portion 34 from the semiconductor substrate 10. The dummy conductive portion 34 may be formed of a same material as the gate conductive portion 44.

The gate trench portion 40 and the dummy trench portion 30 of the present example are covered with the interlayer dielectric film 38 at the front surface 21 of the semiconductor substrate 10. Note that the bottom portions of the dummy trench portion 30 and the gate trench portion 40 may have curved surfaces which are convex downward (curved shapes in the XZ cross section).

In the bottom portion of the trench portion, the trench bottom portion 75 of the P type is provided. The trench bottom portion 75 of the present example is provided below the accumulation region 16. In the depth direction of the semiconductor substrate 10, a lower end of the trench bottom portion 75 may be positioned below a bottom portion of the gate trench portion 40. In other words, the trench bottom portion 75 may cover the bottom portion of the gate trench portion 40.

The trench bottom portion 75 may be a floating layer which is electrically floating. In the present specification, the floating layer refers to a layer which is not electrically connected to any of electrodes such as the emitter electrode 52. By providing the trench bottom portion 75, a turn-on characteristic of the transistor portion 70 is improved. In addition, by providing the trench bottom portion 75, the electric field strength in the bottom portion of the gate trench portion 40 is relaxed, and an avalanche capability is improved.

The transistor portion 70 may have, in a top view, an electron passage region 76 in which the trench bottom portion 75 is not provided. The accumulation region 16 may be provided in the electron passage region 76. In another example, the accumulation region 16 may not be provided. The trench bottom portion 75 may be a floating layer which is electrically floating provided on a center portion side of the active portion 160 further than the electron passage region 76. In another example, the trench bottom portion 75 may have a region which is provided on the edge termination structure portion 190 side further than the electron passage region 76 and in contact with the well region 11.

Since the electron passage region 76 dissociates and electrically floats the trench bottom portion 75 on the center portion side of the active portion 160 from the well region 11 which is fixed at an emitter potential, electrons can flow through the trench bottom portion 75 on the center portion side of the active portion 160 when the transistor portion 70 is conductive. In addition, electrons can flow through the electron passage region 76 when the transistor portion 70 is conductive.

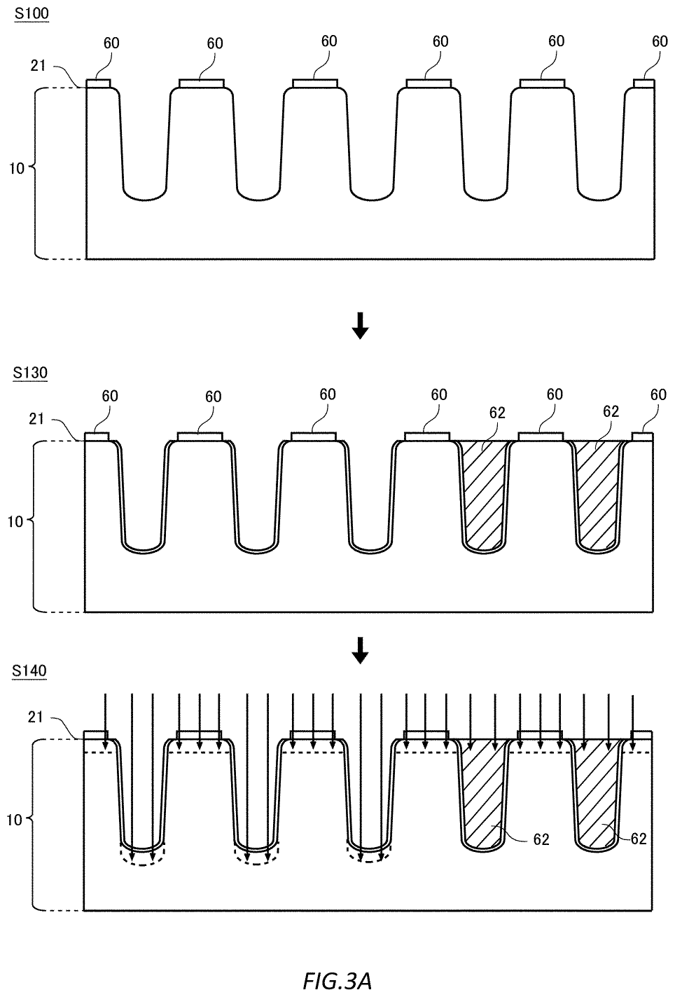

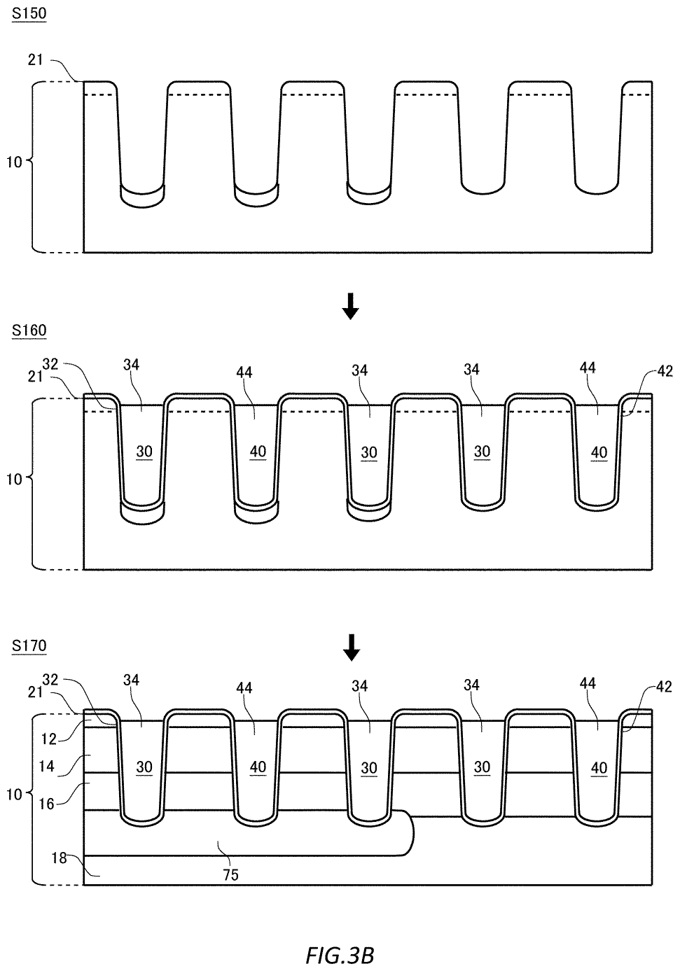

FIGS. 3A and 3B illustrate an example of a manufacturing method of the semiconductor device 100 according to the embodiment 1. Herein, a process relating to forming the trench bottom portion 75 is mainly described, and descriptions of other processes are omitted.

In step S100, by forming a trench etch mask 60 at the front surface 21 of the semiconductor substrate 10 and etching by using the trench etch mask 60, a plurality of trenches are formed. The trench is formed by etching to a depth reaching a region which will become the drift region 18 (a region which remains without being provided with another doping region in a subsequent doping region forming process).

In step S130, an oxide film having a thickness of 50 nm to 200 nm is formed. The trench etch mask 60 may be removed before forming the oxide film. In addition, among the plurality of trenches, an implantation mask 62 is formed in a trench in which the trench bottom portion 75 is not formed at its bottom portion. The implantation mask 62 of the present example is a resist mask. In the present example, for convenience, among the plurality of trenches, a trench in which the trench bottom portion 75 is not formed at its bottom portion may be referred to as a first trench, and a trench in which the trench bottom portion 75 is formed at its bottom portion may be referred to as a second trench.

An upper surface of the implantation mask 62 is provided at a same position as the front surface 21 of the semiconductor substrate 10, or a position deeper than the front surface 21 of the semiconductor substrate 10 in the Z axis direction. That is, the implantation mask 62 of the present example is not provided on the mesa portion, and is provided only in the first trench.

In step S140, ions of a P type dopant are implanted to form the trench bottom portion 75. In the present example, the ions of the dopant are implanted perpendicularly toward the bottom portion of the trench portion from above the plurality of trenches. The dose amount may be appropriately adjusted so as to be a predetermined doping concentration. As an example, the P type dopant is boron (B).

The P type dopant is implanted in the second trench in which the implantation mask 62 is not formed. Further, the P type dopant is also implanted in the mesa portion in which the implantation mask 62 is not formed. In the present example, for convenience, the mesa portion which is adjacent to the first trench may be referred to as a first mesa portion, and the mesa portion which is adjacent to the second trench may be referred to as a second mesa portion. In the mesa portion which is sandwiched between the first trench and the second trench, a side facing the first trench may be considered as the first mesa portion, and a side facing the second trench may be considered as the second mesa portion. The P type dopant is also implanted in the first mesa portion and the second mesa portion. In FIG. 3B, an implantation depth of the P type dopant in the first mesa portion and the second mesa portion are shown by a dashed line.

In step S150, after removing the oxide film from sidewalls of the plurality of trench portions and the mesa portion, in step S160, an oxide film is formed on the sidewalls of the plurality of trench portions. Thereby, damage due to ion implantation is removed together with the old oxide film, and leakage current from the trench is prevented by the new oxide film. These oxide films serve as the dummy dielectric film 32 and the gate dielectric film 42. Further, the plurality of trenches having sidewalls which are covered with the dummy dielectric film 32 and the gate dielectric film 42 are filled with a polysilicon or the like doped with impurities, and the dummy conductive portion 34 and the gate conductive portion 44 are respectively formed. Excess polysilicon or the like deposited at the front surface 21 of the semiconductor substrate 10 is removed by the etching, to form the dummy trench portion 30 and the gate trench portion 40.

In step S170, the ions of the dopant are implanted in the front surface 21 of the semiconductor substrate 10 to form the base region 14 or the like, and then the doping region is formed by thermal diffusion. Thereby, the P type dopant implanted in a bottom portion of the second trench in step S140 diffuses in the trench array direction (X axis direction), and the trench bottom portion 75 which extends across the plurality of second trenches in the trench array direction (X axis direction) is formed. In addition, other than the trench bottom portion 75, the doping region such as the base region 14, the emitter region 12, the contact region 15, and the accumulation region 16 are formed.

In the present example, the P type dopant is implanted in the mesa portion in step S140. However, as illustrated in FIG. 3B, the P type dopant is evenly implanted in the first mesa portion and the second mesa portion. Therefore, since even after the doping region forming process in step S170, dose amounts of the P type dopant implanted in the first mesa portion and the second mesa portion are equivalent and a doping concentration of the base region 14 becomes even, a threshold voltage of the mesa portions in contact with the gate trench portion 40 can be made uniform regardless of whether or not the trench bottom portion 75 is provided at its bottom portion.

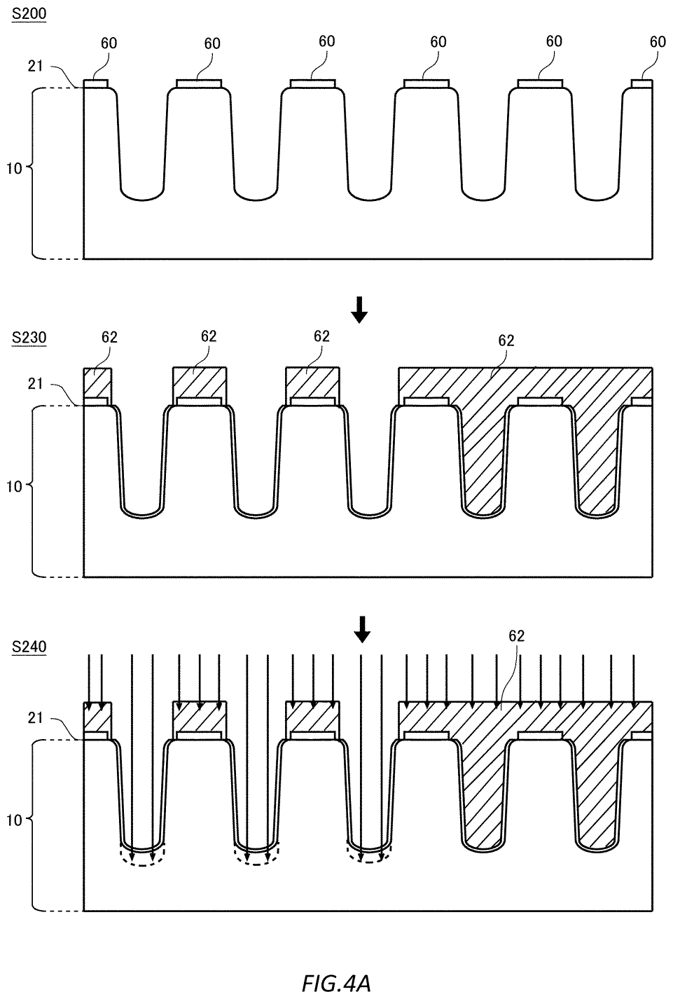

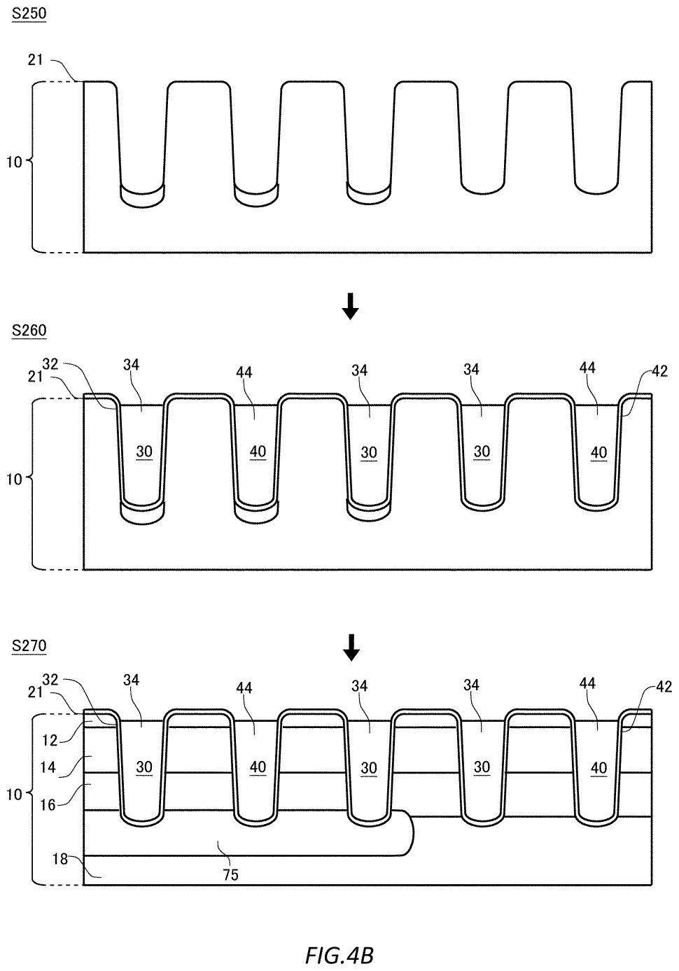

FIG. 4A and FIG. 4B illustrate another example of the manufacturing method of the semiconductor device 100 according to the embodiment 1. The present example differs from the example in FIG. 3A and FIG. 3B in the formation process of the implantation mask 62. Herein, differences from FIG. 3A and FIG. 3B are mainly described, and descriptions of common processes are omitted.

Steps S200 to S220 are the same as steps S100 to S120 of FIG. 3A. In step S230, among the plurality of trenches, the implantation mask 62 is formed in the trench (i.e. the first trench) in which the trench bottom portion 75 is not formed at its bottom portion, on an upper surface of the mesa portion (i.e. the first mesa portion) which is adjacent to the first trench, and on an upper surface of the mesa portion (i.e. the second mesa portion) which is adjacent to the trench (i.e. the second trench) in which the trench bottom portion 75 is formed at its bottom portion.

The implantation mask 62 is formed such that its ends in the trench array direction (X axis direction) and sidewalls of the second trench are aligned. In the present specification, an upper end of the sidewalls of the trench is a point where it intersects the front surface 21 of the semiconductor substrate 10, and aligning the implantation mask 62 with the sidewalls of the trench means that the ends of the implantation mask 62 are positioned at the upper ends of the sidewalls of the trench in the trench array direction (X axis direction). That is, the implantation mask 62 of the present example is provided so as to not only cover the inside of the first trench, but also to cover both the first mesa portion and the second mesa portion.

In step S240, the ions of the P type dopant are implanted to form the trench bottom portion 75. In the present example, the ions of the dopant are implanted perpendicularly toward the bottom portion of the trench portion from above the plurality of trenches. The dose amount may be appropriately adjusted so as to be a predetermined doping concentration. As an example, the P type dopant is boron (B).

The P type dopant is implanted in the second trench in which the implantation mask 62 is not formed. However, the P type dopant is not implanted in the mesa portion in which the implantation mask 62 is formed. That is, in the present example, the P type dopant is implanted only in the second trench.

In step S250 to step S270, the dummy trench portion 30, the gate trench portion 40, and the doping region are formed after removing the oxide film from the sidewalls of the plurality of trenches, but a description thereof is omitted since they are in common with step S150 to step S170.

In the present example, in step S240, the P type dopant is implanted only in the second trench, and is not implanted in either the first mesa portion or the second mesa portion. Therefore, the P type dopant is not implanted in any mesa portion before the doping region forming process in step S270, and in the doping region forming process in step S270, the P type dopant is evenly implanted in the first mesa portion and the second mesa portion. Thus, since the doping concentration of the base region 14 is even in each of the mesa portions, the threshold voltage of the mesa portion in contact with the gate trench portion 40 can be made uniform regardless of whether or not the trench bottom portion 75 is provided at its bottom portion.

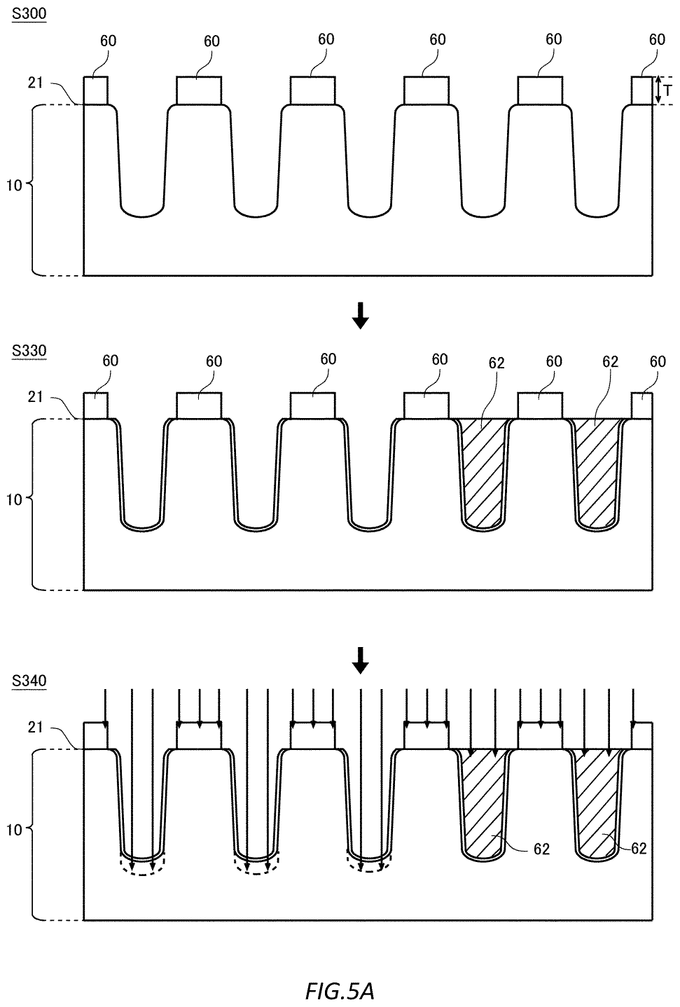

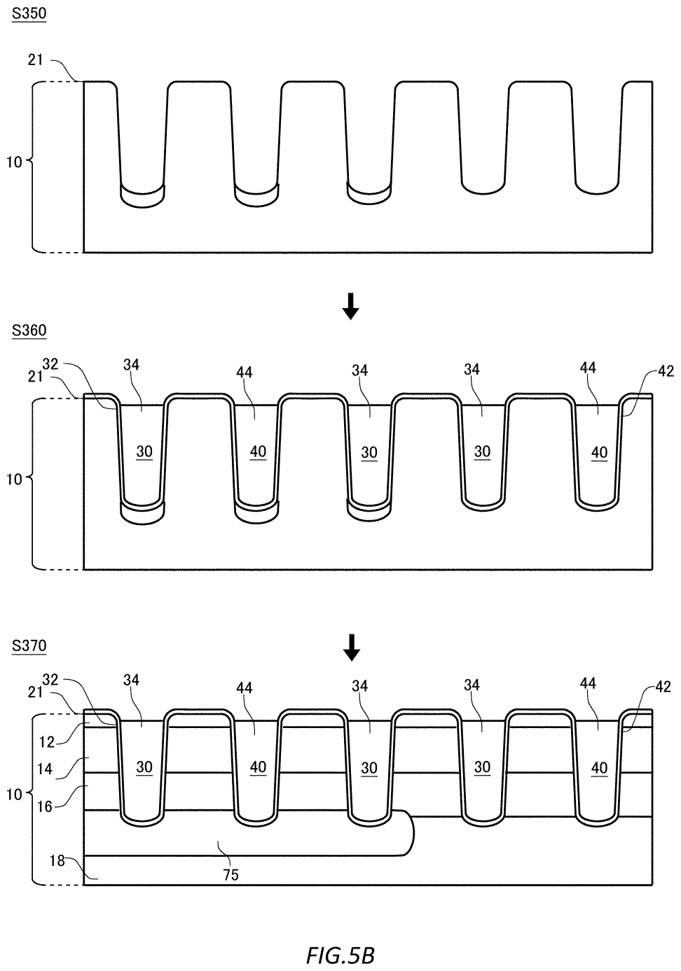

FIG. 5A and FIG. 5B illustrate another example of the manufacturing method of the semiconductor device 100 according to the embodiment 1. The present example differs from the example illustrated in FIG. 3A and FIG. 3B in the formation process of the trench etch mask 60. Herein, differences from the example illustrated in FIG. 3A and FIG. 3B are mainly described, and descriptions of common processes are omitted.

In step S300, by forming the trench etch mask 60 at the front surface 21 of the semiconductor substrate 10 and etching by using the trench etch mask 60, the plurality of trenches are formed. A thickness T of the trench etch mask 60 is 0.3 μm or more and 1 μm or less. The thickness T of the trench etch mask 60 of the present example is greater than a thickness of the trench etch mask 60 used in the example illustrated in FIG. 3A and FIG. 3B.

In step S340, ions of the P type dopant are implanted to form the trench bottom portion 75 by using the trench etch mask 60 and the implantation mask 62. The P type dopant is implanted in the second trench in which the implantation mask 62 is not formed. However, the P type dopant is not implanted in the mesa portion in which the trench etch mask 60 remains. That is, in the present example, the P type dopant is implanted only in the second trench.

In step S350, the oxide film which is provided on the trench etch mask 60 provided on the upper surface of the mesa portion and on the sidewalls of the plurality of trench portions is removed. In step S350 to step S370, the dummy trench portion 30, the gate trench portion 40, and the doping region are formed, but a description thereof is omitted since they are in common with step S160 to step S170.

In the present example, since the trench etch mask 60 thickly formed in step S300 is also used in a formation process of the trench bottom portion 75 in step S340, the P type dopant is implanted only in the second trench and is not implanted in the mesa portion. Therefore, the P type dopant is not implanted in any mesa portion before the doping region forming process in step S370, and in the doping region forming process in step S370, the P type dopant is evenly implanted in the mesa portion. Thus, since the doping concentration of the base region 14 is even in each of the mesa portions, the threshold voltage of the mesa portion in contact with the gate trench portion 40 can be made uniform regardless of whether or not the trench bottom portion 75 is provided at its bottom portion.

In the present example, by setting the thickness T of the trench etch mask 60 to 0.3 μm or more and 1 μm or less, the trench etch mask 60 can have a thickness sufficient to be usable as the implantation mask even after etching.

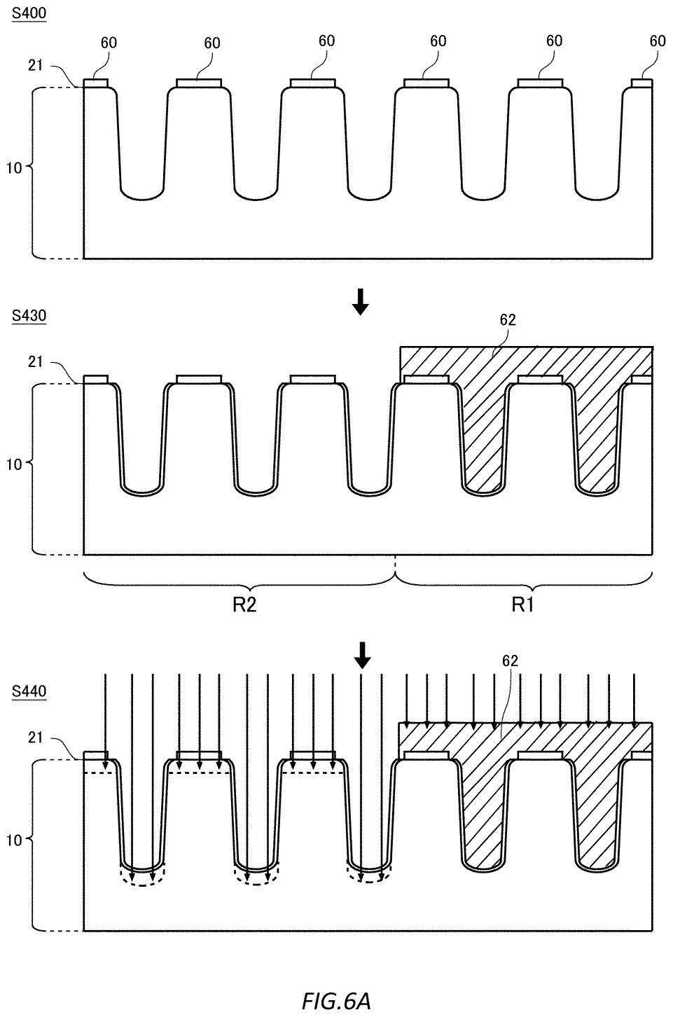

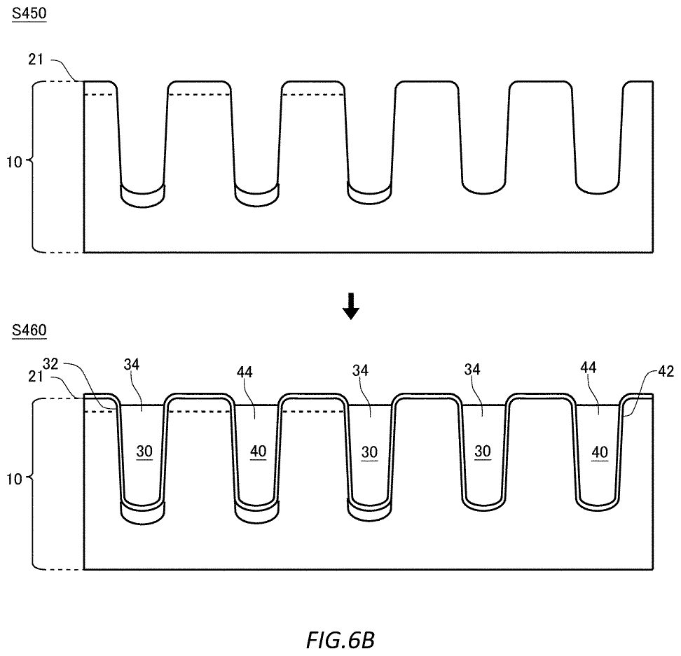

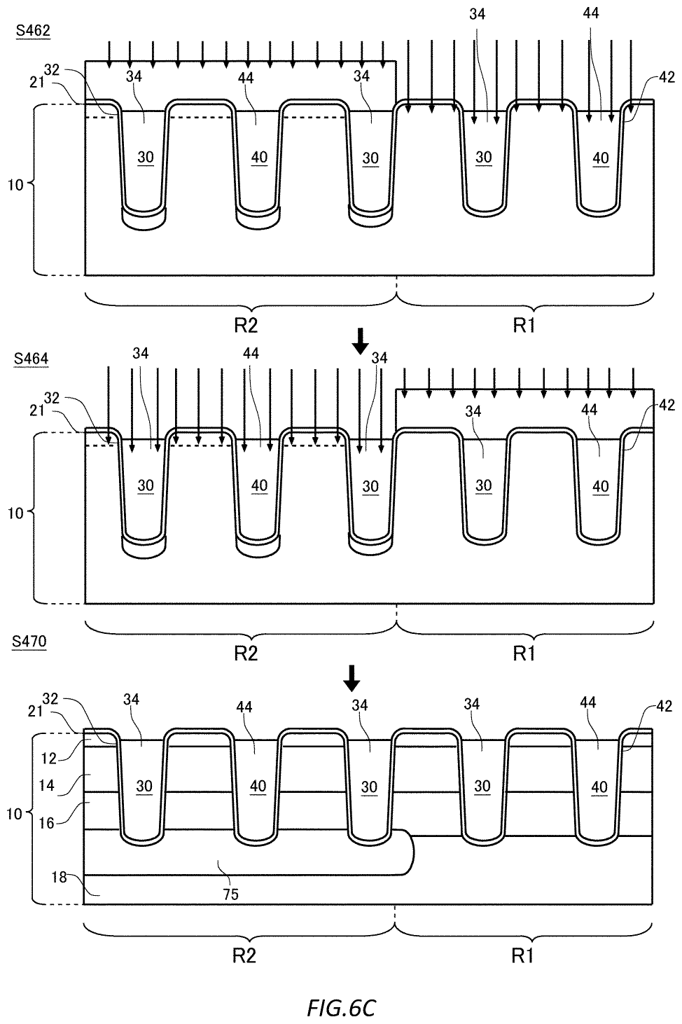

FIG. 6A to FIG. 6C illustrate another example of the manufacturing method of the semiconductor device 100 according to the embodiment 1. The present example differs from the example illustrated in FIG. 3A and FIG. 3B in the formation process of the doping region. Herein, differences from the example illustrated in FIG. 3A and FIG. 3B are mainly described, and descriptions of common processes are omitted.

Step S400 is the same as step S100 of FIG. 3A. In step S430, the implantation mask 62 is formed in a first region R1 in which the trench (i.e. the first trench) in which the trench bottom portion 75 is not formed at its bottom portion is formed. The implantation mask 62 of the present example may be provided only in the first trench, and may be provided in the first trench and on the mesa portion (i.e. the first mesa portion) adjacent to the first trench in the first region R1.

In step S440, ions of the P type dopant are implanted to form the trench bottom portion 75 in a second region R2 in which the implantation mask 62 is not formed. In the second region R2, the P type dopant is implanted in the second trench and the mesa portion (i.e. the second mesa portion) adjacent to the second trench in which the implantation mask 62 is not formed. In FIG. 6B, an implantation depth of the P type dopant in the first mesa portion and the second mesa portion are shown by a dashed line. In steps S450 to S460, after the oxide film is removed from the sidewalls of the plurality of trenches, the dummy trench portion 30, the gate trench portion 40, and the doping region are formed, but a description thereof is omitted since they are in common with step S160 to step S170.

In step S462, the P type dopant is implanted in the first mesa portion adjacent to the first trench in the first region R1 to form the base region 14. In step S464, the P type dopant is implanted in the second mesa portion to form the base region 14.

A dose amount of the P type dopant implanted in the second mesa portion of the second region R2 in step S464 is smaller than a dose amount of the P type dopant implanted in the first mesa portion of the first region R1 in step S462. The dose amount of the P type dopant implanted in the second mesa portion, that is, a total dose amount of the P type dopant implanted in the second mesa portion in step S440 and step S464 is equivalent to the dose amount of the P type dopant implanted in the first mesa portion. Note that either the P type dopant implantation process in step S462 or step S464 may be performed first.

In step S470, the ions of the dopant are implanted in the front surface 21 of the semiconductor substrate 10 to form the emitter region 12 or the like, and then the doping region is formed by thermal diffusion. Thereby, the P type dopant implanted in the bottom portion of the second trench in step S440 diffuses in the trench array direction (X axis direction), and the trench bottom portion 75 which extends across the plurality of second trenches in the trench array direction (X axis direction) is formed. In addition, other than the trench bottom portion 75, the doping region such as the base region 14, the emitter region 12, the contact region 15, and the accumulation region 16 are formed.

In the present example, in step S440, the P type dopant is implanted in the second mesa portion of the second region R2. However, since the dose amounts of the P type dopant implanted in the first mesa portion and the second mesa portion are equivalent and a doping concentration of the base region 14 becomes even by implanting more P type dopant in step S462 than in step S464, the threshold voltage of the mesa portions in contact with the gate trench portion 40 can be made uniform regardless of whether or not the trench bottom portion 75 is provided at its bottom portion.

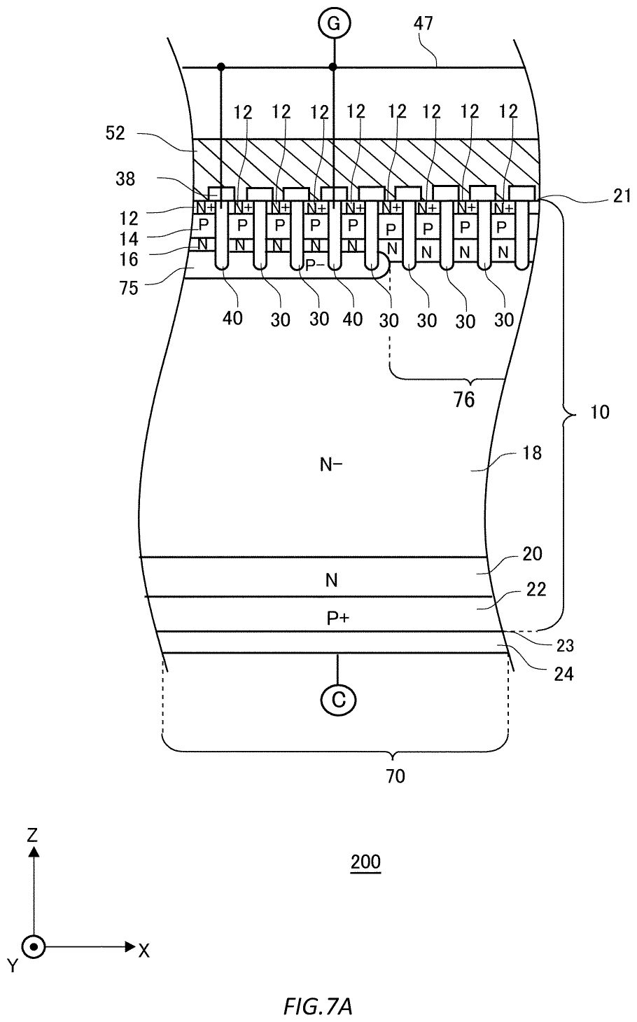

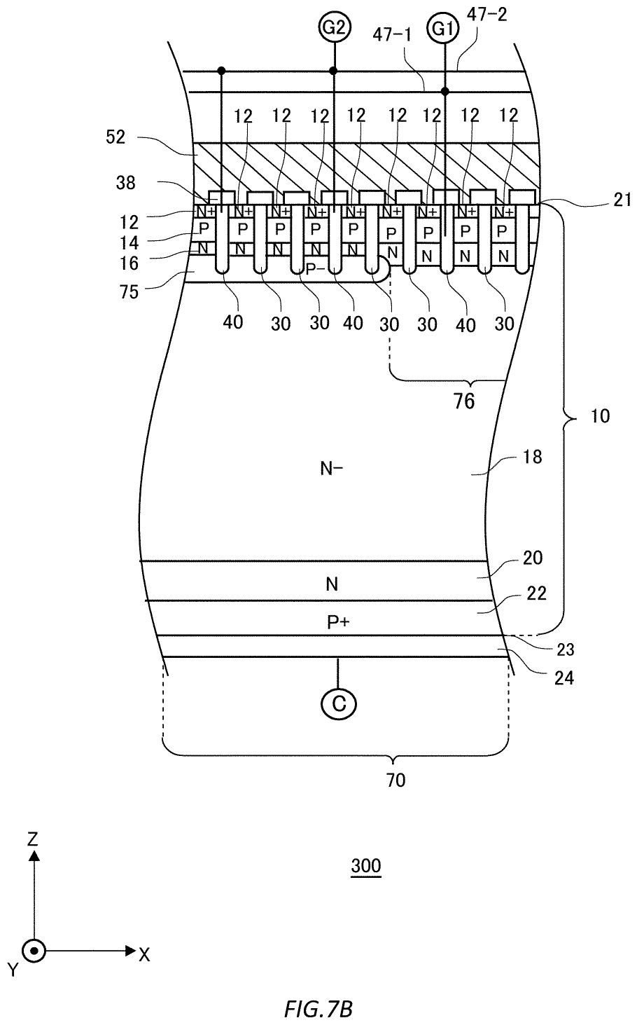

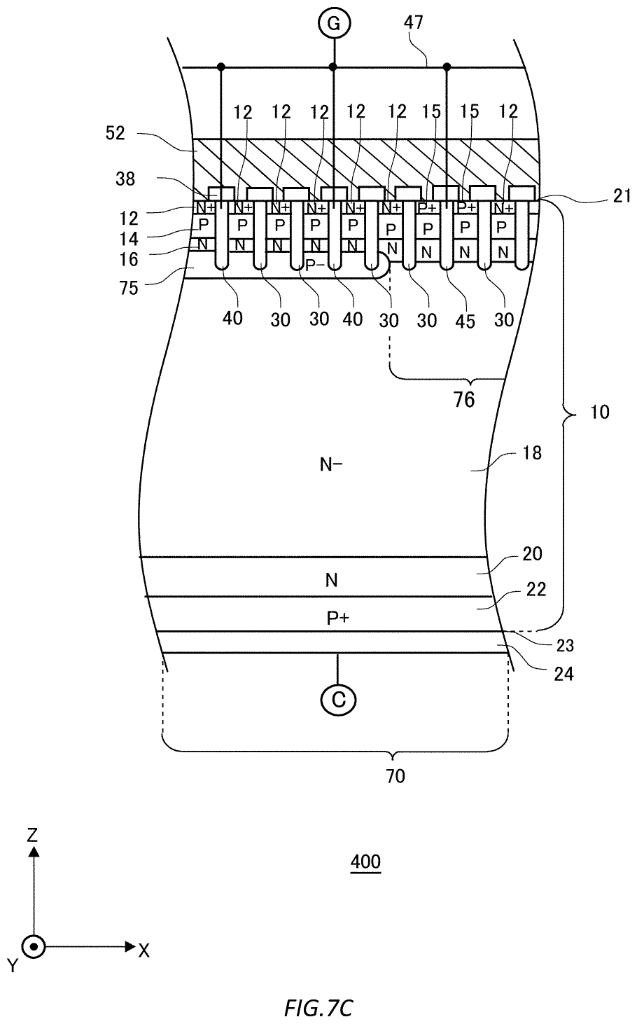

FIG. 7A illustrates an example of a cross section of a semiconductor device 200 according to an embodiment 2. Herein, members which are in common with the semiconductor device 100 are given common references, and differences from the semiconductor device 100 are mainly described.

The semiconductor device 200 of the present example include the plurality of trench portions including the gate trench portion 40 and the dummy trench portion 30. In the present example, for convenience, among the plurality of trench portions, the trench portion in which the trench bottom portion 75 is not provided at its bottom portion may be referred to as a first trench portion, and the trench portion in which the trench bottom portion 75 is provided at its bottom portion may be referred to as a second trench portion.

FIG. 7A schematically illustrates connections between the trench portions and electrodes in the semiconductor device 200 of the present example. In the present example, a region in which the plurality of first trench portions in which the trench bottom portion 75 is not provided are arrayed in series, and a region in which the plurality of second trench portions in which the trench bottom portion 75 is provided are arrayed in series are provided alternately in the trench array direction (X axis direction). The region in which the plurality of first trench portions are arrayed in series constitutes the electron passage region 76. The trench bottom portion 75 is provided extending in the trench array direction (X axis direction) across the plurality of second trench portions arrayed in series.

The first trench portions arrayed in series of the present example are dummy trench portions 30 which are set at the emitter potential.

As described in relation to the embodiment 1, if the method described in the embodiment 1 is not followed in the formation process of the trench bottom portion 75, while the P type dopant is implanted in the mesa portion (i.e. the second mesa portion) adjacent to the trench (i.e. the second trench) in which the trench bottom portion 75 is formed, the mesa portion (i.e. the first mesa portion) adjacent to the trench (i.e. the first trench) in which the trench bottom portion 75 is not formed is covered by the implantation mask 62. That is, the dose amount of the P type dopant implanted in the first mesa portion is smaller than the dose amount of the P type dopant implanted in the second mesa portion, and a threshold voltage of the first mesa portion may be reduced in relation to a threshold voltage of the second mesa portion.

In the semiconductor device 200 of the present example, the first trench portion is the dummy trench portion 30 which is not connected to a gate pad G. That is, by designating only trench portions not in contact with the first mesa portion as the gate trench portions 40, the threshold voltage of the mesa portions in contact with the gate trench portion 40 can be made uniform.

The second trench portion of the present example is the gate trench portion 40 set at a gate potential or the dummy trench portion 30 set at the emitter potential. In addition, a dummy gate trench portion 45 shown in FIG. 7C may be included in the second trench portions. The dummy gate trench portion 45 refers to a trench portion which is set at the gate potential and is not in contact with the emitter region 12. The gate trench portion 40 is electrically connected to the gate pad G via the gate runner 47. By designating only trench portions not in contact with the first mesa portion as the gate trench portions 40, the threshold voltage of the mesa portions in contact with the gate trench portion 40 can be made uniform. In addition, in the mesa portion between the first trench portion and the second trench portion, the P type dopant implanted on a side of the second trench portion (the second mesa portion) may diffuse to a side of the first trench portion (the first mesa portion) in which the P type dopant is not implanted, and thus the doping concentration of the base region 14 of the second mesa portion may be reduced. Therefore, in the second mesa portion between the first trench portion and the second trench portion may have a more reduced threshold voltage compared to the second mesa portion between the second trench portions. Therefore, the second trench portion adjacent to the first trench portion may be designated as the dummy trench portion 30 or the dummy gate trench portion 45. When the second trench portion adjacent to the first trench portion is designated as the dummy gate trench portion 45, the emitter region 12 may be provided in the second mesa portion on the side of the adjacent second trench portion so that the second trench portion may be operated as the gate trench portion 40, while the emitter region 12 may not be provided in the second mesa portion on the side of the adjacent first trench portion. In addition, in the second mesa portions on both sides of the second trench portion adjacent to the first trench portion, when a concentration difference and a threshold voltage difference of the base regions 14 are small and not a problem, the second trench portion may be designated as the gate trench portion 40 having the emitter region 12 in the second mesa portions on both sides.

FIG. 7B illustrates an example of a cross section of a semiconductor device 300 according to an embodiment 3. Herein, members which are in common with the semiconductor device 100 are given common references, and differences are mainly described.

FIG. 7B schematically illustrates connections between the trench portions and electrodes in the semiconductor device 300 of the present example. In the present example, among the plurality of trench portions, the plurality of first trench portions arrayed in series in the trench array direction (X axis direction) has the gate trench portion 40 which is connected to a gate pad G1 via a first gate runner 47-1, and the plurality of second trench portions arrayed in series in the trench array direction (X axis direction) has the gate trench portion 40 which is connected to a gate pad G2 via a second gate runner 47-2. The dummy trench portion 30 is connected to the emitter electrode 52 and is set at the emitter potential.

As described above, in the formation process of the trench bottom portion 75, the dose amount of the P type dopant implanted in the mesa portion (i.e. the first mesa portion) adjacent to the trench (i.e. the first trench) in which the trench bottom portion 75 is not formed is different from the dose amount of the P type dopant implanted in the mesa portion (i.e. the second mesa portion) adjacent to the trench (i.e. the second trench) in which the trench bottom portion 75 is formed.

In the semiconductor device 300 of the present example, the gate trench portion 40 of the plurality of first trench portions and the plurality of second trench portions are connected to different gate pads via different gate runners. Thereby, the gate pads G1 and G2 transmit signals at different timings according to a difference in threshold voltage, and thus timings of turning the plurality of first trench portions and the plurality of second trench portions on and/or off can be synchronized.

Alternatively, the first gate runner 47-1 and the second gate runner 47-2 may have different gate wiring resistances. For example, the first gate runner 47-1 and the second gate runner 47-2 may have resistor portions of different resistance values inserted midway in their paths, may be formed of materials of different resistances, or may have different cross-sectional areas. In this case, even when the gate pads G1 and G2 are the same gate pad, since signal transmission speeds to the first trench portion and the second trench portion are different according to the gate wiring resistances of the first gate runner 47-1 and the second gate runner 47-2, the timings of turning the plurality of first trench portions and the plurality of second trench portions on and/or off can be synchronized. In the present example, similarly to the semiconductor device 200 illustrated in FIG. 7A, the second trench portion adjacent to the first trench portion may be the dummy trench portion 30 or the dummy gate trench portion 45, or when the concentration difference of adjacent base regions 14 is small, may be the gate trench portion 40. The dummy gate trench portion 45 may be included in the other second trench portions. In addition, in the mesa portion of the first trench portion adjacent to the second trench portion, the P type dopant implanted on the side of the second trench portion (the second mesa portion) may diffuse to the side of the first trench portion (the first mesa portion) in which the P type dopant is not implanted, and thus the concentration of the base region 14 of the first mesa portion may be increased. Therefore, the threshold voltage in the first mesa portion between the first trench portion and the second trench portion may be higher compared to that in the first mesa portion between the first trench portions. Therefore, the first trench portion adjacent to the second trench portion may be designated as the dummy trench portion 30 or the dummy gate trench portion 45. When the first trench portion adjacent to the second trench portion is designated as the dummy gate trench portion 45, the emitter region 12 may be provided in the first mesa portion on the side of the adjacent first trench portion so that the first trench portion may be operated as the gate trench portion 40, while the emitter region 12 may not be provided in the first mesa portion on the side of the adjacent second trench portion. In addition, in the first mesa portions on both sides of the first trench portion adjacent to the second trench portion, when a concentration difference and a threshold voltage difference of the base regions 14 are small and not a problem, the first trench portion may be designated as the gate trench portion 40 having the emitter region 12 in the first mesa portions on both sides. The dummy gate trench portion 45 may be included in the other first trench portions.

FIG. 7C illustrates an example of a cross section of a semiconductor device 400 according to an embodiment 4. Herein, members which are in common with the semiconductor device 100 are given common references, and differences are mainly described.

FIG. 7C schematically illustrates connections between the trench portions and electrodes in the semiconductor device 400 of the present example. In the present example, among the plurality of trench portions, the dummy gate trench portion 45 of the plurality of first trench portions arrayed in series in the trench array direction (X axis direction) and the gate trench portion 40 of the plurality of second trench portions arrayed in series in the trench array direction (X axis direction) are connected to the gate pad G via the gate runner 47. Herein, the dummy gate trench portion 45 refers to the trench portion which is set at the gate potential and is not in contact with the emitter region 12. The dummy trench portion 30 is connected to the emitter electrode 52 and is set at the emitter potential.

As described above, in the formation process of the trench bottom portion 75, the dose amount of the P type dopant implanted in the mesa portion (i.e. the first mesa portion) adjacent to the trench (i.e. the first trench) in which the trench bottom portion 75 is not formed is different from the dose amount of the P type dopant implanted in the mesa portion (i.e. the second mesa portion) adjacent to the trench (i.e. the second trench) in which the trench bottom portion 75 is formed.

In the semiconductor device 400 of the present example, the dummy gate trench portion 45 of the plurality of first trench portions and the gate trench portion 40 of the plurality of second trench portions are connected to the gate pad via the gate runner. Since the first trench portion is the dummy gate trench portion 45 which is not in contact with the emitter region 12, electrons are not conducted from the front surface 21 even when the base region 14 forms an inversion channel. Since the second trench portion is the gate trench portion 40 which includes the emitter region 12, electrons are conducted from the front surface 21 even when the base region 14 forms an inversion channel. As described above, by designating only trench portions not in contact with the first mesa portion as the gate trench portions 40, the threshold voltage of the mesa portions in contact with the gate trench portion 40 can be made uniform.

Note that, although the contact region 15 is provided in contact with the dummy gate trench portion 45 instead of the emitter region 12 in FIG. 7C, it is not limited to this. The contact region 15 may not be formed and may be the base region 14. In addition, the emitter region 12 may not be formed adjacent to the dummy trench portion 30 of the first trench portion. In the present example, similarly to the semiconductor device 200 illustrated in FIG. 7A, the second trench portion adjacent to the first trench portion may be the dummy trench portion 30 or the dummy gate trench portion 45, or when the concentration difference of adjacent base regions 14 is small, may be the gate trench portion 40. The dummy gate trench portion 45 may be included in the other second trench portions.

Although it has been described above that the trench bottom portion 75 is formed when impurities of the P type implanted respectively in the second trenches diffuse by less than one mesa width and connect with one another, the present invention is also applicable to a case where a diffusion width of the impurities of the P type is different. Even in a case where diffusion of the impurities of the P type is narrow and do not connect to each other, and the trench bottom portion 75 is formed discretely, the threshold of each mesa portion can be made uniform by similarly applying the above-described invention.

On the other hand, when the diffusion is wider than one mesa width, the trench bottom portion 75 is formed in the trench portions positioned at ends of the trench bottom portion 75, even though ions of the P type are not implanted in its bottom portions. In this case, the trench portions (may be referred to as a third trench portion) are similar to the first trench portion, and the threshold of each mesa portion can be made uniform.

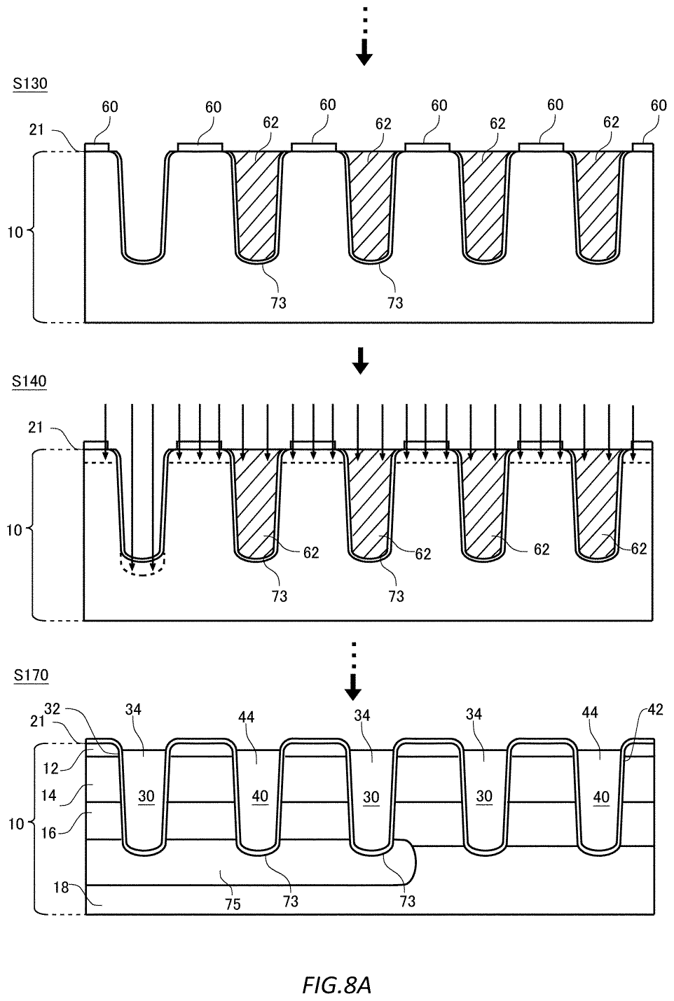

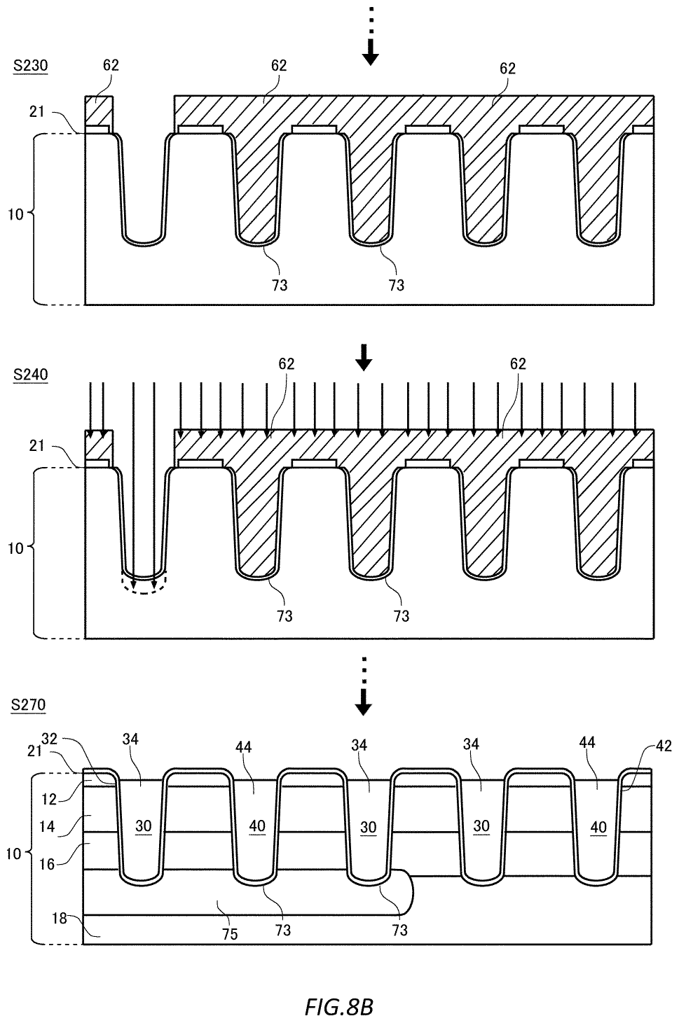

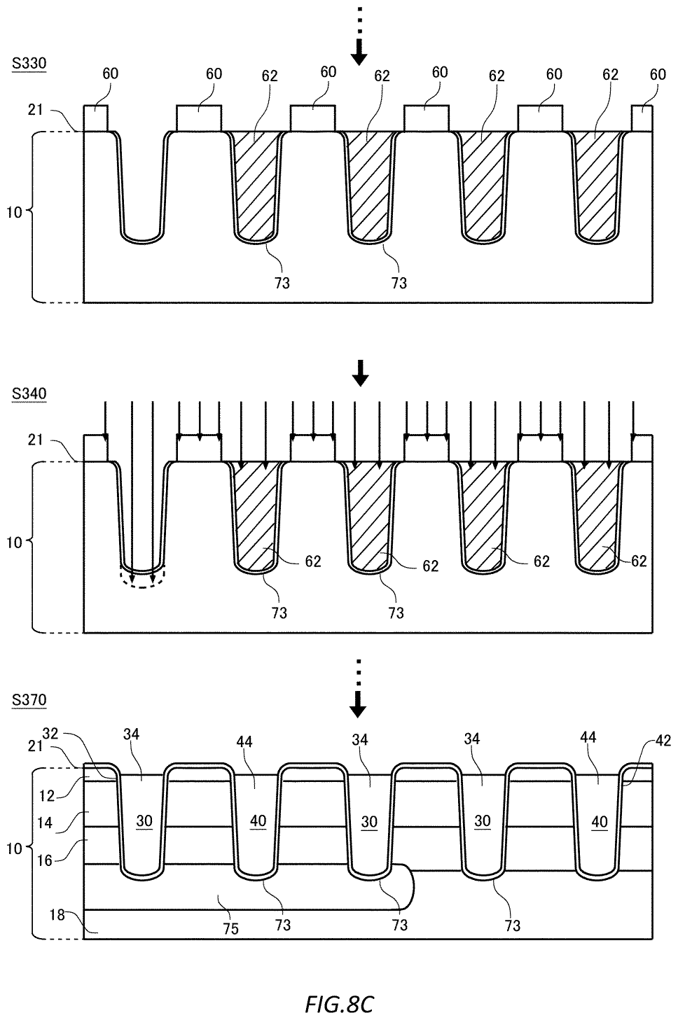

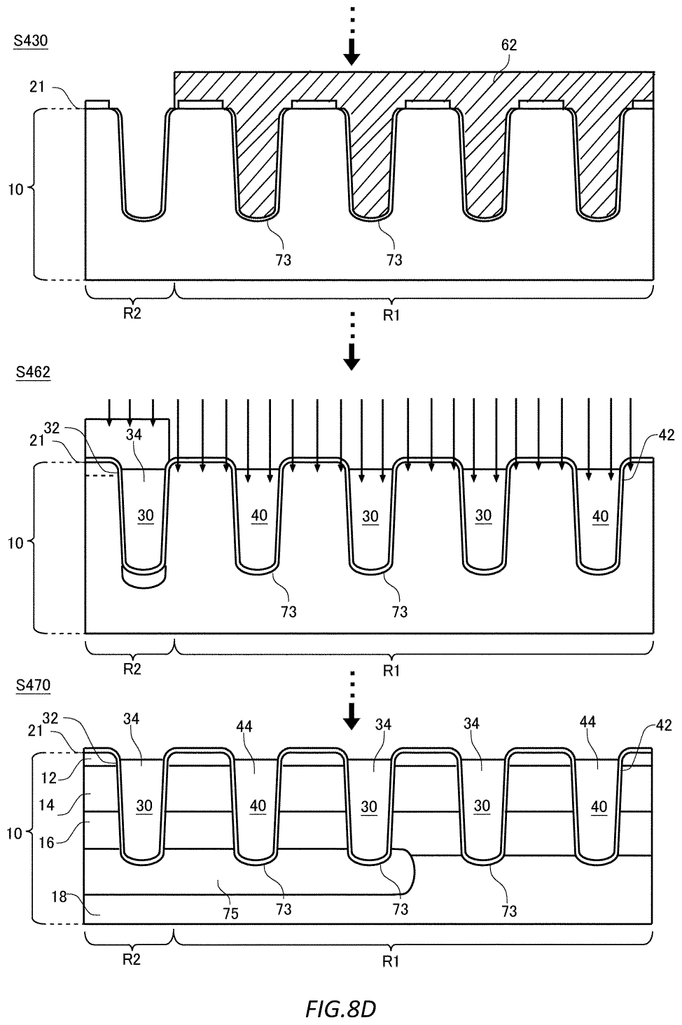

FIG. 8A illustrates another example of the manufacturing method of the semiconductor device 100 according to the embodiment 1 when a third trench 73 is included. Herein, modifications relating to the third trench from the process illustrated in FIG. 3A and FIG. 3B are mainly described, and descriptions of other processes are omitted.

In step S130, an oxide film having a thickness of 50 nm to 200 nm is formed in a third trench 73 similarly to the first trench and the second trench. The trench etch mask 60 may be removed before forming the oxide film. In addition, among the plurality of trenches, the implantation mask 62 is formed in the third trench 73 similarly to the first trench. The implantation mask 62 of the present example is a resist mask.

The upper surface of the implantation mask 62 is provided at the same position as the front surface 21 of the semiconductor substrate 10, or a position deeper than the front surface 21 of the semiconductor substrate 10 in the Z axis direction. That is, the implantation mask 62 of the present example is not provided on the mesa portion, and is provided only in the first trench and the third trench 73.

In step S140, the ions of the P type dopant are implanted to form the trench bottom portion 75. The P type dopant is implanted in the second trench in which the implantation mask 62 is not formed. Further, the P type dopant is also implanted in the mesa portion in which the implantation mask 62 is not formed. In the present example, for convenience, the mesa portion which is adjacent to the first trench and the third trench 73 may be referred to as the first mesa portion, and the mesa portion which is adjacent to the second trench may be referred to as the second mesa portion. In the mesa portion which is sandwiched between the third trench 73 and the second trench, a side facing the third trench 73 may be considered as the first mesa portion, and a side facing the second trench may be considered as the second mesa portion. The P type dopant is also implanted in the first mesa portion and the second mesa portion. In FIG. 8A, the implantation depth of the P type dopant in the first mesa portion and the second mesa portion are shown by a dashed line.

Although an illustration is omitted in FIG. 8A, in step S150 and step S160, in the plurality of trenches including the third trench 73, the dummy trench portion 30 and the gate trench portion 40 may be formed as illustrated in FIG. 3B. In step S170, the ions of the dopant are implanted in the front surface 21 of the semiconductor substrate 10 to form the base region 14 or the like, and then the doping region is formed by thermal diffusion. Thereby, the P type dopant implanted in the bottom portion of the second trench in step S140 diffuses in the trench array direction (X axis direction), and the trench bottom portion 75 which extends across the plurality of second trenches in the trench array direction (X axis direction) is formed, and at this time, the trench bottom portion 75 is also formed in a bottom portion of the third trench 73. Note that, although two third trenches 73 are provided and formed as the gate trench portion 40 and the dummy trench portion 30 in FIG. 8A, three or more may be provided, and when only one is provided, it may be formed as the gate trench portion 40 or may be formed as the dummy trench portion 30.

FIG. 8B illustrates another example of the manufacturing method of the semiconductor device 100 according to the embodiment 1 when the third trench 73 is included. Herein, modifications relating to the third trench from the process illustrated in FIG. 4A and FIG. 4B are mainly described, and descriptions of other processes are omitted.

In step S230, among the plurality of trenches, the implantation mask 62 is formed in the trench (i.e. the first trench and the third trench 73) in which ions of the P type dopant are not implanted to form the trench bottom portion 75 at its bottom portion, on an upper surface of the mesa portion (i.e. the first mesa portion) which is adjacent to the first trench, and on an upper surface of the mesa portion (i.e. the second mesa portion and the first mesa portion) which is adjacent to the trench (i.e. the second trench) in which ions of the P type dopant are implanted to form the trench bottom portion 75 at its bottom portion.

In step S240, the ions of the P type dopant are implanted to form the trench bottom portion 75. The P type dopant is implanted in the second trench in which the implantation mask 62 is not formed. However, the P type dopant is not implanted in the mesa portion in which the implantation mask 62 is formed. That is, in the present example, the P type dopant is implanted only in the second trench.

Although an illustration is omitted in FIG. 8B, in step S250 and step S260, in the plurality of trenches including the third trench 73, the dummy trench portion 30 and the gate trench portion 40 may be formed as illustrated in FIG. 4B. In step S270, the ions of the dopant are implanted in the front surface 21 of the semiconductor substrate 10 to form the base region 14 or the like, and then the doping region is formed by thermal diffusion. Thereby, the P type dopant implanted in the bottom portion of the second trench in step S240 diffuses in the trench array direction (X axis direction), and the trench bottom portion 75 which extends across the plurality of second trenches in the trench array direction (X axis direction) is formed, and at this time, the trench bottom portion 75 is also formed in the bottom portion of the third trench 73. Note that, although two third trenches 73 are provided and formed as the gate trench portion 40 and the dummy trench portion 30 in FIG. 8B, three or more may be provided, and when only one is provided, it may be formed as the gate trench portion 40 or may be formed as the dummy trench portion 30.

FIG. 8C illustrates another example of the manufacturing method of the semiconductor device 100 according to the embodiment 1 when the third trench 73 is included. Herein, modifications relating to the third trench from the process illustrated in FIG. 5A and FIG. 5B are mainly described, and descriptions of other processes are omitted.

In step S330, the implantation mask 62 is formed inside the third trench 73 and the first trench.

In step S340, ions of the P type dopant are implanted to form the trench bottom portion 75 by using the trench etch mask 60 and the implantation mask 62. The P type dopant is implanted in the second trench in which the implantation mask 62 is not formed. However, the P type dopant is not implanted in the mesa portion in which the trench etch mask 60 remains. That is, in the present example, the P type dopant is implanted only in the second trench, and is not implanted in the first mesa portion, the second mesa portion, the first trench, and the third trench 73.

Although an illustration is omitted in FIG. 8C, in step S350 and step S360, in the plurality of trenches including the third trench 73, the dummy trench portion 30 and the gate trench portion 40 may be formed as illustrated in FIG. 5B. In step S370, the ions of the dopant are implanted in the front surface 21 of the semiconductor substrate 10 to form the base region 14 or the like, and then the doping region is formed by thermal diffusion. Thereby, the P type dopant implanted in the bottom portion of the second trench in step S340 diffuses in the trench array direction (X axis direction), and the trench bottom portion 75 which extends across the plurality of second trenches in the trench array direction (X axis direction) is formed, and at this time, the trench bottom portion 75 is also formed in the bottom portion of the third trench 73. Note that, although two third trenches are provided and formed as the gate trench portion 40 and the dummy trench portion 30 in FIG. 8C, three or more may be provided, and when only one is provided, it may be formed as the gate trench portion 40 or may be formed as the dummy trench portion 30.

FIG. 8D illustrates another example of the manufacturing method of the semiconductor device 100 according to the embodiment 1 when the third trench 73 is included. Herein, modifications relating to the third trench from the process illustrated in FIG. 6A and FIG. 6C are mainly described, and descriptions of other processes are omitted.

In step S430, the implantation mask 62 is formed inside the third trench 73 and the first trench and in the first mesa portion in the first region R1.

Although an illustration is omitted in FIG. 8D, in step S440, ions of the P type dopant are implanted in the second region R2 to form the trench bottom portion 75. Although an illustration is omitted in FIG. 8D, in step S450 and step S460, in the plurality of trenches including the third trench 73, the dummy trench portion 30 and the gate trench portion 40 may be formed as illustrated in FIG. 6B. In step S462, the P type dopant is implanted in the first mesa portion adjacent to the first trench and the third trench 73 in the first region R1 to form the base region 14.

Although an illustration is omitted in FIG. 8D, in step S464, the P type dopant is implanted in the second mesa portion adjacent to the second trench in the second region R2 to form the base region 14. In step S470, the doping region is formed by thermal diffusion. Thereby, the P type dopant implanted in the bottom portion of the second trench in step S440 diffuses in the trench array direction (X axis direction), and the trench bottom portion 75 which extends across the plurality of second trenches in the trench array direction (X axis direction) is formed, and at this time, the trench bottom portion 75 is also formed in the bottom portion of the third trench 73. Note that, although two third trenches are provided and formed as the gate trench portion 40 and the dummy trench portion 30 in FIG. 8D, three or more may be provided, and when only one is provided, it may be formed as the gate trench portion 40 or may be formed as the dummy trench portion 30.

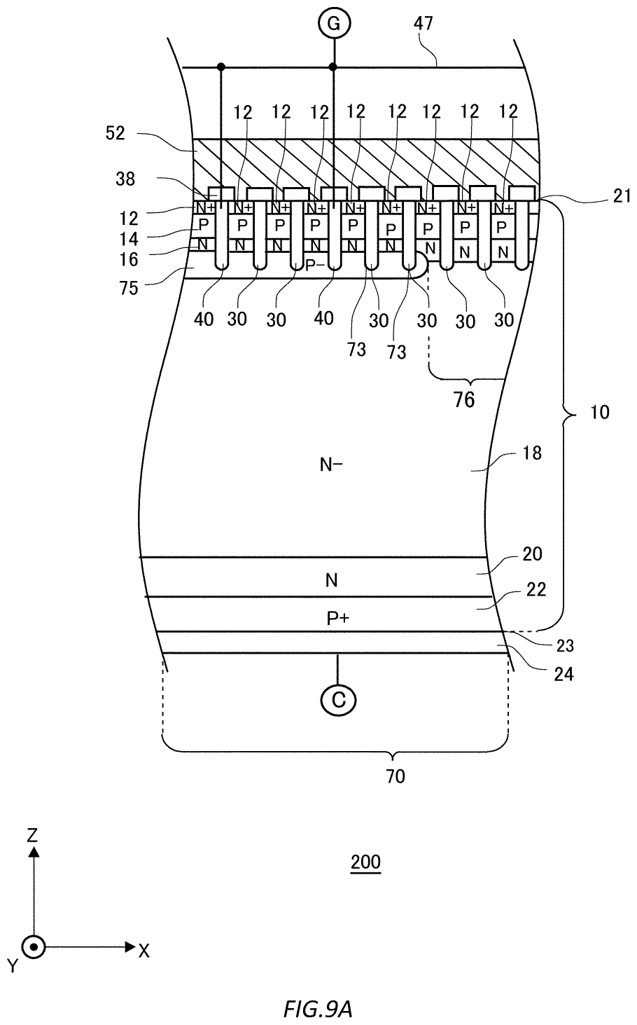

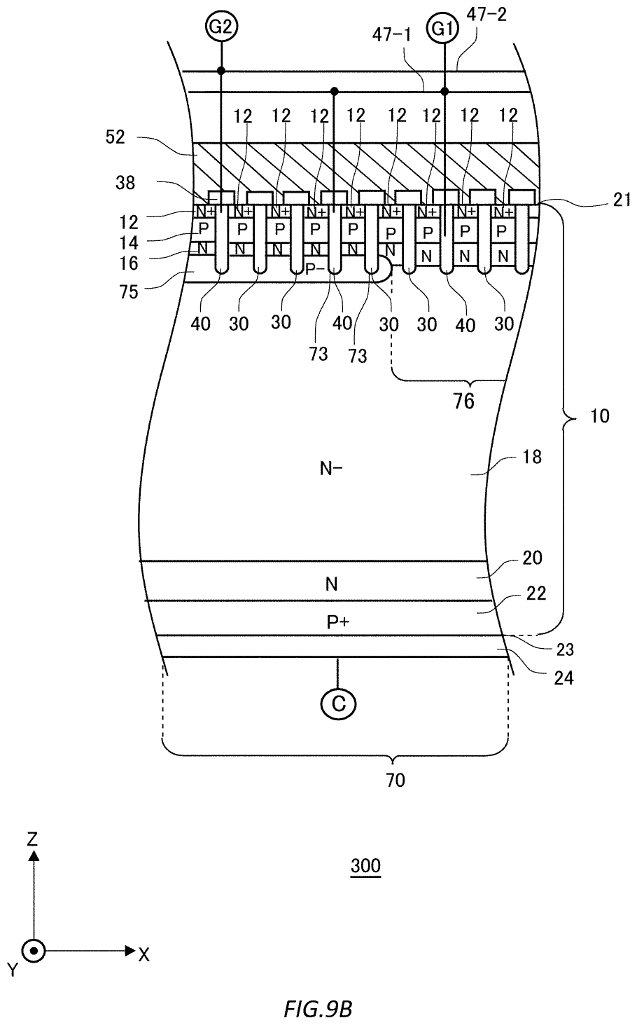

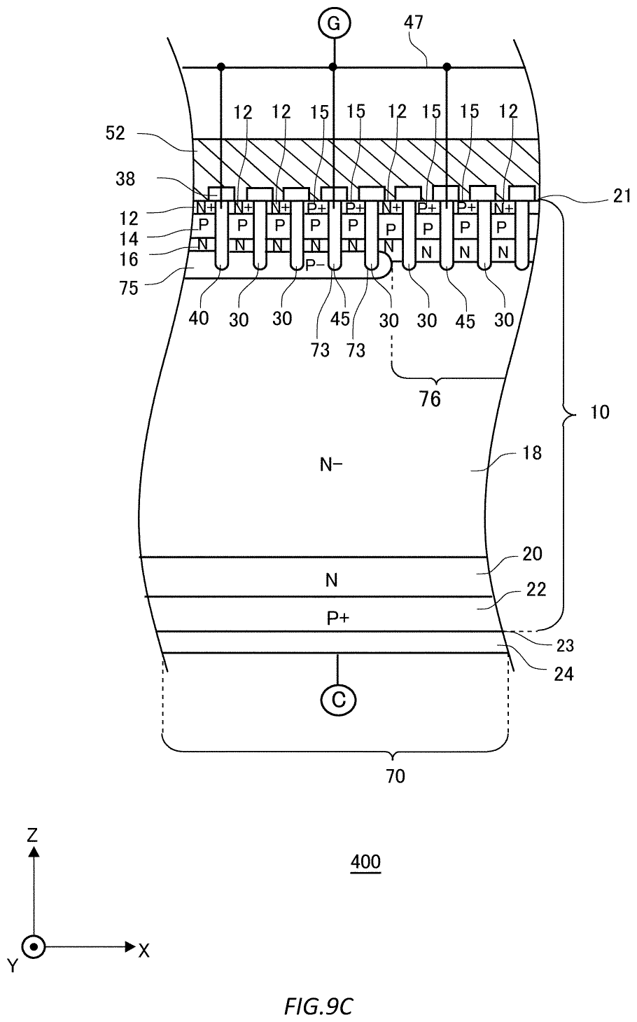

FIG. 9A illustrates another example of the cross section of the semiconductor device 200 according to the embodiment 2 when the third trench portion is included. Herein, modifications relating to the third trench portion from the semiconductor device illustrated in FIG. 7A are mainly described, and descriptions of other structures are omitted.

In FIG. 7A, the trench portion positioned at an end of the trench bottom portion 75 is formed in the second trench. In FIG. 9A, the trench portion positioned at the end of the trench bottom portion 75 is formed in the third trench 73, and ions are not implanted in the adjacent first mesa portion to form the trench bottom portion 75. However, in the present example, since the third trench 73 is formed as the dummy trench portion 30, a channel is not formed in the first mesa portion adjacent to the third trench 73, and variance in the threshold of each conductive mesa portion does not occur. Although two third trenches 73 are provided in FIG. 9A, three or more may be provided, and only one may be provided.

FIG. 9B illustrates another example of the cross section of the semiconductor device 300 according to the embodiment 3 when the third trench portion is included. Herein, modifications relating to the third trench portion from the semiconductor device illustrated in FIG. 7B are mainly described, and descriptions of other structures are omitted.

In FIG. 7B, the trench portion positioned at an end of the trench bottom portion 75 is formed in the second trench. In FIG. 9B, the trench portion positioned at the end of the trench bottom portion 75 is formed in the third trench 73, and ions are not implanted in the adjacent first mesa portion to form the trench bottom portion 75. In the present example, although the third trench 73 is formed as the gate trench portion 40, it is connected to the first gate runner 47-1 similarly to the first trench of the electron passage region 76. Also in the first mesa portion adjacent to the third trench 73, variance in timing of turning the gates of each of the other mesa portions on and/or off does not occur. In addition, the third trench 73 may be formed as the dummy trench portion 30, and also in this case, a channel is not formed in the first mesa portion adjacent to the third trench 73, and variance in the threshold of each conductive mesa portion does not occur. In another example, the gate trench portion 40 formed from the third trench 73 is connected to the first gate runner 47-1, and another first trench portion may not be connected to the first gate runner 47-1 and the second gate runner 47-2. Although two third trenches 73 are provided in FIG. 9B, three or more may be provided, and when only one is provided, it may be formed as the gate trench portion 40 or may be formed as the dummy trench portion 30.

FIG. 9C illustrates another example of the cross section of the semiconductor device 400 according to the embodiment 4 when the third trench portion is included. Herein, modifications relating to the third trench portion from the semiconductor device illustrated in FIG. 7C are mainly described, and descriptions of other structures are omitted.

In FIG. 7C, the trench portion positioned at the end of the trench bottom portion 75 is formed in the second trench. In FIG. 9C, the trench portion positioned at the end of the trench bottom portion 75 is formed in the third trench 73, and ions are not implanted in the adjacent first mesa portion to form the trench bottom portion 75. However, since the third trench 73 is formed as the dummy gate trench portion 45 in the present example, a channel formed in the first mesa portion adjacent to the third trench 73 is not connected to the emitter region 12, and electrons are not conducted. Thus, variance in the threshold of each conductive mesa portion does not occur. In addition, the third trench 73 may be formed as the dummy trench portion 30, and also in this case, a channel is not formed in the first mesa portion adjacent to the third trench 73, and variance in the threshold of each conductive mesa portion does not occur. Although two third trenches 73 are provided in FIG. 9C, three or more may be provided, and when only one is provided, it may be formed as the dummy gate trench portion 45 or may be formed as the dummy trench portion 30. Note that, the third trench 73 in the semiconductor devices 200 and 300 according to the embodiments 2 and 3 may be formed as the dummy gate trench portion 45.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### Item 1

A method for manufacturing a semiconductor device, comprising:
forming a plurality of trenches at a front surface of a semiconductor substrate;
forming an implantation mask in a first trench of the plurality of trenches; and
implanting a dopant of a second conductivity type in a second trench, among the plurality of trenches, in which the implantation mask is not formed, to form a trench bottom portion in a bottom portion of the second trench, wherein
in the implanting the dopant, the dopant of the second conductivity type is also implanted in a first mesa portion adjacent to the first trench and a second mesa portion adjacent to the second trench.

### Item 2

The method for manufacturing the semiconductor device according to item 1, wherein
in the forming the plurality of trenches, a third trench is further formed between the first trench and the second trench,
in the forming the implantation mask, the implantation mask is further formed in the third trench,
in the implanting the dopant, the dopant of the second conductivity type is further implanted in the first mesa portion adjacent to the third trench, and
the method comprises
diffusing the dopant, and further forming the trench bottom portion in a bottom portion of the third trench.

### Item 3

The method for manufacturing the semiconductor device according to item 1 or 2, wherein
an upper surface of the implantation mask is provided at a same position as the front surface of the semiconductor substrate, or at a position deeper than the front surface of the semiconductor substrate in a depth direction of the semiconductor substrate.

### Item 4

A method for manufacturing a semiconductor device, comprising:
forming a plurality of trenches at a front surface of a semiconductor substrate;
forming an implantation mask in a first trench of the plurality of trenches; and
implanting a dopant of a second conductivity type in a second trench, among the plurality of trenches, in which the implantation mask is not formed, to form a trench bottom portion in a bottom portion of the second trench, wherein
in the forming the implantation mask, the implantation mask is also formed on an upper surface of a first mesa portion adjacent to the first trench and an upper surface of a second mesa portion adjacent to the second trench.

### Item 5

The method for manufacturing the semiconductor device according to item 4, wherein
in the forming the plurality of trenches, a third trench is further formed between the first trench and the second trench,
in the forming the implantation mask, the implantation mask is further formed in the third trench and the upper surface of the first mesa portion adjacent to the third trench, and
the method comprises
diffusing the dopant, and further forming the trench bottom portion in a bottom portion of the third trench.

### Item 6

The method for manufacturing the semiconductor device according to item 4 or 5, wherein
in the forming the implantation mask, the implantation mask is formed such that ends of the implantation mask in a trench array direction and sidewalls of the second trench are aligned.

### Item 7

A method for manufacturing a semiconductor device, comprising:
forming a trench etch mask at a front surface of a semiconductor substrate;
forming a plurality of trenches at the front surface of the semiconductor substrate by using the trench etch mask;
forming an implantation mask in a first trench of the plurality of trenches; and
implanting a dopant of a second conductivity type in a second trench in which the implantation mask is not formed, to form a trench bottom portion in a bottom portion of the second trench by using the trench etch mask and the implantation mask.

### Item 8

The method for manufacturing the semiconductor device according to item 7, wherein
in the forming the plurality of trenches, a third trench is further formed between the first trench and the second trench,
in the forming the implantation mask, the implantation mask is further formed in the third trench, and
the method comprises
diffusing the dopant, and further forming the trench bottom portion in a bottom portion of the third trench.

### Item 9

The method for manufacturing the semiconductor device according to item 7 or 8, wherein
a thickness of the trench etch mask is 0.3 μm or more and 1 μm or less.

### Item 10

A method for manufacturing a semiconductor device, comprising:
forming a plurality of trenches at a front surface of a semiconductor substrate;
forming an implantation mask in a first region in which a first trench of the plurality of trenches is formed;
implanting a trench bottom by implanting a dopant of a second conductivity type in a second trench among the plurality of trenches and a second mesa portion adjacent to the second trench in a second region in which the implantation mask is not formed, to form a trench bottom portion in a bottom portion of the second trench;
implanting a first base by implanting the dopant of the second conductivity type in a first mesa portion adjacent to the first trench in the first region to form a base region, after removing the implantation mask from the first region; and
implanting a second base by implanting the dopant of the second conductivity type in the second mesa portion to form the base region.

### Item 11

The method for manufacturing the semiconductor device according to item 10, wherein
in the forming the plurality of trenches, a third trench is further formed between the first trench and the second trench,
in the forming the implantation mask, the implantation mask is further formed in the third trench in the first region,
in the implanting the first base, the dopant of the second conductivity type is further implanted in the first mesa portion adjacent to the third trench, and
the method comprises
diffusing the dopant, and further forming the trench bottom portion in a bottom portion of the third trench.

### Item 12

The method for manufacturing the semiconductor device according to item 10 or 11, wherein
a dose amount in the implanting the second base is smaller than the dose amount in the implanting the first base.

### Item 13

The method for manufacturing the semiconductor device according to item 10 or 11, wherein
a dose amount of the dopant implanted in the second mesa portion is equivalent to the dose amount of the dopant implanted in the first mesa portion.

### Item 14

A semiconductor device, comprising:
a plurality of trench portions including a first trench portion and a second trench portion; and
a trench bottom portion of a second conductivity type provided in a bottom portion of the second trench portion, wherein
the first trench portion in which the trench bottom portion is not provided is a dummy trench portion or a dummy gate trench portion.

### Item 15

A semiconductor device, comprising:
a plurality of trench portions including a first trench portion and a second trench portion;
a trench bottom portion of a second conductivity type provided in a bottom portion of the second trench portion;
a first gate runner connected to the first trench portion in which the trench bottom portion is not provided; and
a second gate runner, different from the first gate runner, connected to the second trench portion.

### Item 16

The semiconductor device according to item 14, further comprising:
a third trench portion between the first trench portion and the second trench portion, wherein
the trench bottom portion is provided in a bottom portion of the third trench portion, and
the third trench portion is the dummy trench portion or the dummy gate trench portion.

### Item 17

The semiconductor device according to item 15, further comprising:
a third trench portion between the first trench portion and the second trench portion, wherein
the trench bottom portion is provided in a bottom portion of the third trench portion, and
the third trench portion is the dummy trench portion or the dummy gate trench portion.

### Item 18

The semiconductor device according to item 15, further comprising:
a third trench portion between the first trench portion and the second trench portion, wherein
the trench bottom portion is provided in a bottom portion of the third trench portion, and
the third trench portion is connected to the first gate runner.

### Item 19

The semiconductor device according to item 14, further comprising:
a third trench portion between the first trench portion and the second trench portion, wherein
the trench bottom portion is provided in a bottom portion of the third trench portion, and
the semiconductor device comprises
a first gate runner connected to the third trench portion, and
a second gate runner, different from the first gate runner, connected to the second trench portion.

### Item 20

The semiconductor device according to any one of items 15, 17, or 18, wherein
the first gate runner and the second gate runner are connected to different gate pads.

### Item 21

The semiconductor device according to any one of items 15, 18, or 19, wherein
the first gate runner and the second gate runner have different gate wiring resistances.

### Item 22

The semiconductor device according to item 14, wherein
the second trench portion adjacent to the first trench portion is the dummy trench portion or the dummy gate trench portion.

### Item 23

The semiconductor device according to item 15, wherein
the second trench portion adjacent to the first trench portion is a dummy trench portion or a dummy gate trench portion.

### Item 24

The semiconductor device according to item 15, wherein
the first trench portion adjacent to the second trench portion is a dummy trench portion or a dummy gate trench portion.

### EXPLANATION OF REFERENCES

10 semiconductor substrate; 11 well region; 12 emitter region; 14 base region; 15 contact region; 16 accumulation region; 18 drift region; 20 buffer region; 21 front surface; 22 collector region; 23 back surface; 24 collector electrode; 29 linear portion; 30 dummy trench portion; 31 edge portion; 32 dummy dielectric film; 34 dummy conductive portion; 38 interlayer dielectric film; 39 linear portion; 40 gate trench portion; 41 edge portion; 42 gate dielectric film; 44 gate conductive portion; 45 dummy gate trench portion; 47 gate runner; 48 semiconductor gate runner; 49 contact hole; 50 gate metal layer; 52 emitter electrode; 54 contact hole; 56 contact hole; 60 trench etch mask; 62 implantation mask; 70 transistor portion; 73 third trench; 75 trench bottom portion; 76 electron passage region; 92 guard ring; 94 field plate; 100 semiconductor device; 160 active portion; 190 edge termination structure portion; 200 semiconductor device; 300 semiconductor device; 400 semiconductor device.

What is claimed is:

1. A method for manufacturing a semiconductor device, comprising:
forming a plurality of trenches at a front surface of a semiconductor substrate;
forming an implantation mask in a first trench of the plurality of trenches; and
implanting a dopant of a second conductivity type in a second trench, among the plurality of trenches, in which the implantation mask is not formed, to form a trench bottom portion in a bottom portion of the second trench, wherein
in the implanting the dopant, the dopant of the second conductivity type is also implanted in a first mesa portion adjacent to the first trench and a second mesa portion adjacent to the second trench.

2. The method for manufacturing the semiconductor device according to claim 1, wherein
in the forming the plurality of trenches, a third trench is further formed between the first trench and the second trench,
in the forming the implantation mask, the implantation mask is further formed in the third trench,
in the implanting the dopant, the dopant of the second conductivity type is further implanted in the first mesa portion adjacent to the third trench, and
the method comprises
diffusing the dopant, and further forming the trench bottom portion in a bottom portion of the third trench.

3. The method for manufacturing the semiconductor device according to claim 1, wherein
an upper surface of the implantation mask is provided at a same position as the front surface of the semiconductor substrate, or at a position deeper than the front surface of the semiconductor substrate in a depth direction of the semiconductor substrate.

4. The method for manufacturing the semiconductor device according to claim 2, wherein
an upper surface of the implantation mask is provided at a same position as the front surface of the semiconductor substrate, or at a position deeper than the front surface of the semiconductor substrate in a depth direction of the semiconductor substrate.

5. The method for manufacturing the semiconductor device according to claim 1, wherein
the implantation mask is a resist mask.

6. The method for manufacturing the semiconductor device according to claim 1, comprising:
forming a gate trench portion in the second trench.

7. A method for manufacturing a semiconductor device, comprising:
forming a trench etch mask at a front surface of a semiconductor substrate;
forming a plurality of trenches at the front surface of the semiconductor substrate by using the trench etch mask;
forming an implantation mask in a first trench of the plurality of trenches; and
implanting a dopant of a second conductivity type in a second trench in which the implantation mask is not formed, to form a trench bottom portion in a bottom portion of the second trench by using the trench etch mask and the implantation mask.

8. The method for manufacturing the semiconductor device according to claim 7, wherein
in the forming the plurality of trenches, a third trench is further formed between the first trench and the second trench,
in the forming the implantation mask, the implantation mask is further formed in the third trench, and
the method comprises
diffusing the dopant, and further forming the trench bottom portion in a bottom portion of the third trench.

9. The method for manufacturing the semiconductor device according to claim 7, wherein
a thickness of the trench etch mask is 0.3 μm or more and 1 μm or less.

10. The method for manufacturing the semiconductor device according to claim 8, wherein
a thickness of the trench etch mask is 0.3 μm or more and 1 μm or less.

11. The method for manufacturing the semiconductor device according to claim 7, wherein
the implantation mask is a resist mask.

12. The method for manufacturing the semiconductor device according to claim 7, comprising:
forming a gate trench portion in the second trench.

13. A semiconductor device, comprising:
a plurality of trench portions including a first trench portion and a second trench portion; and
a trench bottom portion of a second conductivity type provided in a bottom portion of the second trench portion, wherein
the first trench portion in which the trench bottom portion is not provided is a dummy trench portion or a dummy gate trench portion.

14. The semiconductor device according to claim 13, further comprising:
a third trench portion between the first trench portion and the second trench portion, wherein
the trench bottom portion is provided in a bottom portion of the third trench portion, and
the third trench portion is the dummy trench portion or the dummy gate trench portion.

15. The semiconductor device according to claim 13, further comprising:
a third trench portion between the first trench portion and the second trench portion, wherein
the trench bottom portion is provided in a bottom portion of the third trench portion, and
the semiconductor device comprises
a first gate runner connected to the third trench portion, and
a second gate runner, different from the first gate runner, connected to the second trench portion.

16. The semiconductor device according to claim 15, wherein
the first gate runner and the second gate runner have different gate wiring resistances.

17. The semiconductor device according to claim 13, wherein
the second trench portion adjacent to the first trench portion is the dummy trench portion or the dummy gate trench portion.
